(19) United States
(12) Patent Application Publication
(10) Pub. No.: US 2025/0089545 A1
(43) Pub. Date: Mar. 13, 2025

(54) METHOD FOR MANUFACTURING DISPLAY DEVICE

(71) Applicant: Samsung Display Co., Ltd., Yongin-si (KR)

(72) Inventors: WONKYU CHOE, Yongin-si (KR); DUCKJUNG LEE, Yongin-si (KR)

(21) Appl. No.: 18/639,800

(22) Filed: Apr. 18, 2024

(30) Foreign Application Priority Data
Sep. 11, 2023 (KR) 10-2023-0120517

(51) Int. Cl. H10K 71/20; H10K 59/12; H10K 59/122; H10K 71/15; H10K 71/60

(52) U.S. Cl. CPC H10K 71/221; H10K 59/1201; H10K 59/122; H10K 71/15; H10K 71/60

(57) ABSTRACT

The method for manufacturing a display device according to one or more embodiments of the present disclosure may include preparing a substrate including a display area, a pad area, a peripheral area, a first electrode, and an intermediate layer, the first electrode and the intermediate layer being in the display area, forming a preliminary first lift-off layer on the substrate, forming a first photoresist pattern on the preliminary first lift-off layer, having a photo-opening part overlapping with the display area, etching the preliminary first lift-off layer to form a first lift-off layer exposing the display area, forming a second electrode on the intermediate layer through the photo opening part, and removing the first lift-off layer and the first photoresist pattern.

### CROSS-REFERENCE TO RELATED APPLICATION

The present application claims priority to and the benefit of Korean Patent Application No. 10-2023-0120517, filed on Sep. 11, 2023, in the Korean Intellectual Property Office, the entire content of which is incorporated herein by reference.

### BACKGROUND

### 1. Field

The present disclosure herein relates to a method for manufacturing a display device, more particularly, to a method for manufacturing a display device wherein a manufacturing process is simplified.

### 2. Description of the Related Art

Display devices include light-emitting elements positioned on a substrate and pads which are electrically connected therewith. Diverse electrical signals may be applied to the light-emitting elements through the pads. The light-emitting element may include a common electrode located on multiple emission layers. The common electrode is a layer commonly provided on the multiple emission layers and may be continuously provided on the multiple emission layers.

When manufacturing the common electrode, it is desirable for the pads applying external electrical signals to not be covered by the common electrode. Accordingly, when manufacturing the common electrode, the common electrode is formed in a preset area of a substrate, and as a result, a mask is used. However, due to repeated use, the mask may become damaged and thus may be replaced periodically. Therefore, the manufacturing cost of a display device increases, and there are defects of going through a process for accurately aligning the substrate and the mask during the manufacturing process.

### SUMMARY

Aspects of some embodiments of the present disclosure are directed to a simplified method for manufacturing a display device.

According to some embodiments of the present disclosure, there is provided a method for manufacturing a display device including preparing a substrate including a display area, a pad area, a peripheral area, a first electrode, and an intermediate layer, the first electrode and the intermediate layer being in the display area, forming a preliminary first lift-off layer on the substrate, forming a first photoresist pattern having a photo-opening part overlapping with the display area, on the preliminary first lift-off layer, etching the preliminary first lift-off layer to form a first lift-off layer exposing the display area, forming a second electrode on the intermediate layer through the photo-opening part, and removing the first lift-off layer and the first photoresist pattern.

In one or more embodiments, the method may further include after forming the second electrode, forming an optical layer on the second electrode through the photo-opening part.

In one or more embodiments, the first lift-off layer may overlap with the pad area on a plane.

In one or more embodiments, the first lift-off layer may include polytetrafluoroethylene (PTFE).

In one or more embodiments, the forming of the first lift-off layer may include etching the preliminary first lift-off layer by a first solvent including fluorine by using the first photoresist pattern as a mask.

In one or more embodiments, the first solvent may include hydrofluoroether (HFE).

In one or more embodiments, the removing the first lift-off layer and the first photoresist pattern may include treating the first lift-off layer and the first photoresist pattern with a second solvent including fluorine.

In one or more embodiments, the preparing of the substrate may include preparing a base substrate in which the display area and the pad area are defined, forming the first electrode on the base substrate so as to overlap with the display area, forming a pixel definition layer defining a pixel opening part exposing a portion of the first electrode, and a liquid repelling part including a liquid repelling material is included, and forming the intermediate layer on the first electrode.

In one or more embodiments, at least a portion of the liquid repelling part may be removed by the etching process during the forming of the first lift-off layer.

In one or more embodiments, the forming the intermediate layer may include forming a hole transport region on the first electrode, forming an emission layer on the hole transport region, and forming an electron transport region on the emission layer.

In one or more embodiments, the forming the intermediate layer may be performed through an inkjet process.

In one or more embodiments, the forming the second electrode may be performed through a deposition process.

In one or more embodiments, the method may further include forming a preliminary second lift-off layer on the substrate, forming a second photoresist pattern which overlaps the pad area, on the preliminary second lift-off layer, etching the preliminary second lift-off layer to form a second lift-off layer exposing the display area, forming an encapsulation layer on the second electrode using the second photoresist pattern as a mask, and removing the second lift-off layer and the second photoresist pattern.

In one or more embodiments, the second lift-off layer may not overlap the display area on a plane, and the peripheral area on a plane.

In one or more embodiments, the forming the second lift-off layer may include etching the preliminary second lift-off layer by a third solvent including fluorine by using the second photoresist pattern as a mask.

In one or more embodiments, the removing the second lift-off layer and the second photoresist layer may include treating the second lift-off layer and the second photoresist pattern with a fourth solvent including fluorine.

According to some embodiments of the present disclosure, there is provided a method for manufacturing a display device according to the present disclosure including preparing a base substrate in which a display area including multiple pixel areas and a pad area are defined, forming a first electrode and a pixel definition layer on the base substrate, the pixel definition layer defining pixel-opening parts, each one of the pixel-opening parts overlapping a pixel area, providing an intermediate layer in the pixel-opening parts by an inkjet printing method, forming a first lift-off layer exposing the display area and including fluorine, and a first photoresist pattern in which a photo-opening part exposing the display area is defined, forming a second electrode on the intermediate layer through the photo-opening part, and removing the first lift-off layer and the first photoresist pattern.

In one or more embodiments, the method may further include forming an optical layer on the second electrode through the photo opening part.

In one or more embodiments, the forming of the first lift-off layer and the first photoresist pattern may include forming a preliminary lift-off layer on the display area and the pad area, forming the first photoresist pattern on the preliminary first lift-off layer, and etching the preliminary first lift-off layer using the first photoresist pattern as a mask to form the first lift-off layer.

In one or more embodiments, the pixel definition layer may include a first pixel definition part disposed on the base substrate, and a second pixel definition part disposed on the first pixel definition part and including a liquid-repelling material, wherein at least a portion of the second pixel definition part may be removed during the etching of the preliminary first lift-off layer.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1A illustrates a perspective view of a display device according to one or more embodiments of the present disclosure;

FIG. 1B illustrates a cross-sectional view of a display device according to one or more embodiments of the present disclosure;

FIG. 2A and FIG. 2B illustrate cross-sectional views according to one or more embodiments of the present disclosure;

FIG. 3 illustrates a plan view of a display panel according to one or more embodiments of the present disclosure;

FIG. 4 illustrates an enlarged plan view of a portion of a display device according to one or more embodiments of the present disclosure;

FIG. 5 illustrates a cross-sectional view of a display device according to one or more embodiments of the present disclosure;

FIG. 6A and FIG. 6B illustrate enlarged cross-sectional views of portions of the cross-sections of display devices according to one or more embodiments of the present disclosure;

FIG. 7 illustrates a flowchart of a method for manufacturing a display device according to one or more embodiments of the present disclosure;

FIG. 8A to FIG. 8Q illustrate diagrams schematically showing some steps of the method for manufacturing a display device according to one or more embodiments of the present disclosure;

FIG. 9 illustrates a flowchart showing some steps of the method for manufacturing a display device according to one or more embodiments of the present disclosure;

FIG. 10A to FIG. 10K illustrate diagrams schematically showing some steps of the method for manufacturing a display device according to one or more embodiments of the present disclosure; and

FIG. 11A to FIG. 11H illustrate diagrams schematically showing some steps of the method for manufacturing a display device according to one or more embodiments of the present disclosure.

### DETAILED DESCRIPTION

Hereinafter, embodiments of the present disclosure will be explained referring to attached drawings.

In the description, it will be understood that when an element (or region, layer, part, and/or the like.) is referred to as being “on”, “connected to” or “coupled to” another element, it can be directly on, connected or coupled to the other element or intervening elements may be present.

Like reference numerals refer to like elements throughout. In addition, in the drawings, the thickness, the ratio, and the dimensions of constituent elements are exaggerated for effective explanation of technical contents. The term “and/or” includes one or more combinations which may be defined by relevant elements.

It will be understood that, although the terms first, second, and/or the like, may be used herein to describe various elements, these elements should not be limited by these terms. These terms are only used to distinguish one element from another element. For example, a first element could be termed a second element without departing from the scope of the right of the present disclosure. Similarly, a second element could be termed a first element. The singular forms are intended to include the plural forms as well, unless the context clearly indicates otherwise.

In addition, the terms “below”, “beneath”, “on” and “above” are used for explaining the relation of elements shown in the drawings. The terms are relative concept and are explained on the basis of the direction shown in the drawing.

It will be further understood that the terms “comprises” or “comprising,” when used in this specification, specify the presence of stated features, numerals, steps, operations, elements, parts, or the combination thereof, but do not preclude the presence or addition according to one or more other features, numerals, steps, operations, elements, parts, or the combination thereof.

In the description, “directly disposed” may mean that there is no additional layer, film, area and plate between a part, such as a layer, film, area and another part. For example, “directly disposed” may mean that two layers or two members are disposed without using an additional member, such as an adhesive member therebetween.

Unless otherwise defined, all terms (including technical and scientific terms) used herein have the same meaning as commonly understood by one of ordinary skill in the art to which this present disclosure belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

Hereinafter, a display panel according to one or more embodiments of the present disclosure will be explained referring to the drawings.

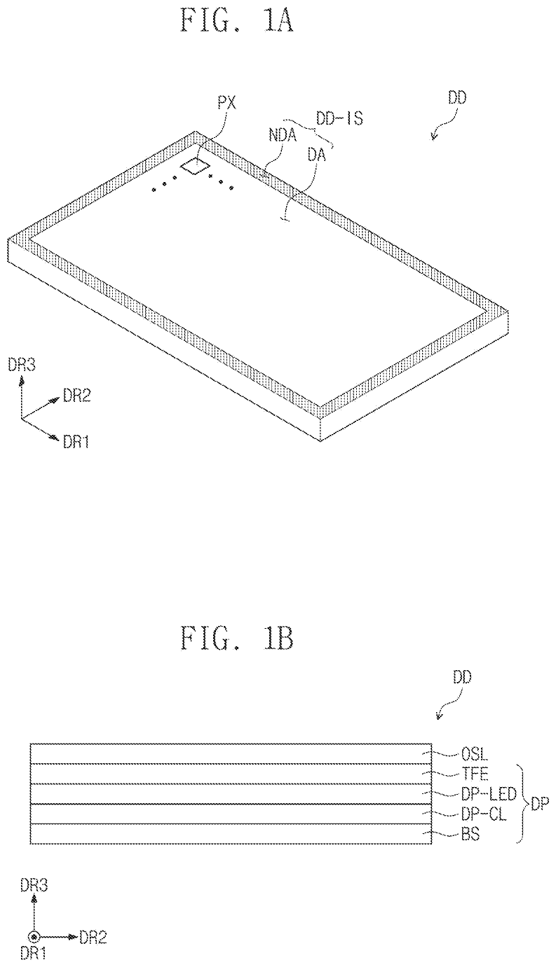

FIG. 1A illustrates a perspective view of a display device according to one or more embodiments of the present disclosure. FIG. 1B illustrates a cross-sectional view of a display device according to one or more embodiments of the present disclosure.

As shown in FIG. 1A, a display device DD may display images through a display surface DD-IS. The display surface DD-IS may be parallel to a plane defined by a first direction DR1 and a second direction DR2. The display surface DD-IS may include a display area DA and a non-display area NDA. A pixel PX may be in the display area DA, and a pixel PX may not be in the non-display area NDA. The non-display area NDA may be defined along the boundary of the display surface DD-IS. The non-display area NDA may surround the display area DA. However, the present disclosure is not limited thereto. In one or more embodiments of the present disclosure, the non-display area NDA may be omitted or located only at one side of the display area DA.

The normal direction of the display surface DD-IS, i.e., the thickness direction of a display panel DP, may be indicated by a third direction DR3. The front surface (or top surface) and the rear surface (or bottom surface) of each layer or unit, explained below may be distinguished by the third direction DR3. However, the first to third directions DR1, DR2 and DR3, shown in one or more embodiments are only examples.

In one or more embodiments of the present disclosure, a display device DD provided with a planar display surface DD-IS is shown, without limitation. The display device DD may include a curved display surface or a three-dimensional display surface. The three-dimensional display surface may include multiple display areas indicating different directions from each other.

As shown in FIG. 1B, the display device DD includes a display panel DP and an optical structure layer OSL located on the display panel DP. The display panel DP may include a base substrate BS, a circuit element layer DP-CL, a display element layer DP-LED, and an encapsulation layer TFE. The base substrate BS may include a synthetic resin substrate or a glass substrate. The circuit element layer DP-CL may include at least one insulation layer and circuit element. The circuit element includes a signal line, the driving circuit of a pixel, and/or the like. The circuit element layer DP-CL may be formed through the forming processes of an insulation layer, a semiconductor layer, and a conductive layer by coating, depositing, and/or the like, and the patterning processes of the insulation layer, the semiconductor layer, and the conductive layer by a photolithography process. The display element layer DP-LED may include at least one display element. The optical structure layer OSL may convert the color of light provided from the display element. The optical structure layer OSL may include a light control pattern and a structure for improving (e.g., increasing) the conversion efficiency of light.

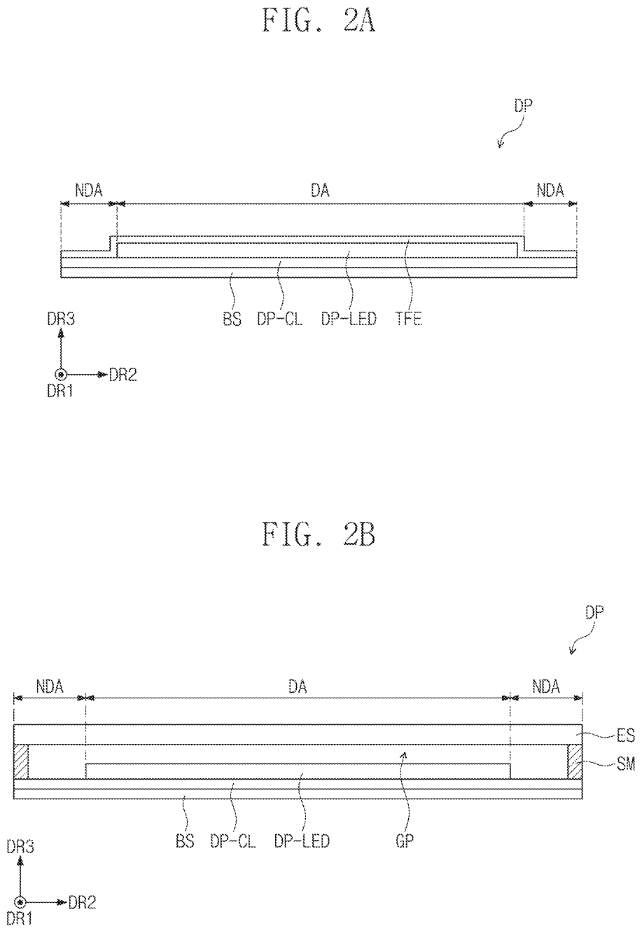

FIG. 2A and FIG. 2B are cross-sectional views of display panels DP according to embodiments of the present disclosure.

As shown in FIG. 2A, a display panel DP includes a base substrate BS, a circuit element layer DP-CL located on the base substrate BS, a display element layer DP-LED, and an encapsulation layer TFE. A display area DA and a non-display area NDA, corresponding to the display area DA and the non-display area NDA, shown in FIG. 1A, may be defined in the display panel DP. In the display panel DP, the display area DA may be defined as an area where a pixel is located. In the display panel DP, the non-display area NDA may be defined as an area in which a pixel is not located and signal lines supporting the operation of the pixel are located. In the detailed description, “an area corresponds to another area” refers to that “areas overlap from each other”, but is not limited to have the same area.

The base substrate BS may include at least one plastic film. The base substrate BS may include a plastic substrate, a glass substrate, a metal substrate, or an organic/inorganic composite material substrate. In one or more embodiments, the base substrate BS may be a thin film glass substrate having a thickness of tens to hundreds of micrometers.

The circuit element layer DP-CL may include at least one insulation layer and a circuit element. The insulation layer may include at least one inorganic layer and at least one organic layer. The circuit element may include signal lines, the driving circuit of a pixel, and/or the like. The details thereon will be described further below.

The display element layer DP-LED may include at least organic light-emitting diodes. The display element layer DP-LED may further include an organic layer, such as a pixel definition layer.

The encapsulation layer TFE may include multiple thin films. A portion of the thin films may be for improving (e.g. increasing) optical efficiency, and a portion of the thin films may be for protecting the organic light-emitting diodes.

Referring to FIG. 2B, different from FIG. 1B and FIG. 2A, a display panel DP may not include an encapsulation layer TFE but may include an encapsulation substrate ES. As shown in FIG. 2B, the display panel DP may include a base substrate BS, a circuit element layer DP-CL located on the base substrate BS, a display element layer DP-LED, an encapsulation substrate ES, and a sealant SM combining the base substrate BS and the encapsulation substrate ES. The encapsulation substrate ES may be spaced apart from the display element layer DP-LED with a certain gap GP. The gap GP may be formed in a vacuum state. However, the present disclosure is not limited thereto, and the gap GP may be charged with the air or an inert gas (hereinafter, external gas). The base substrate BS and the encapsulation substrate ES may include a plastic substrate, a glass substrate, a metal substrate, or an organic/inorganic composite material substrate.

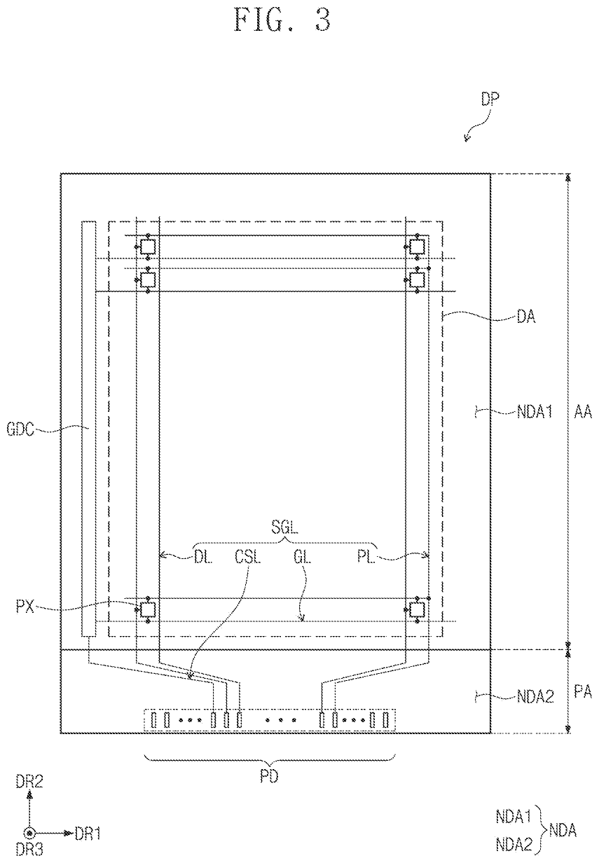

The base substrate BS may be combined with the encapsulation substrate ES by the sealant SM. For example, the sealant may be located along the edge defined by the first direction DR1 and the second direction DR2 of the encapsulation substrate ES. In one or more embodiments, the edge refers to the periphery of the encapsulation substrate ES, overlapping with the non-display area NDA (see, e.g., FIG. 3) of the display panel DP (see, e.g., FIG. 3) on a plane. Accordingly, the sealant SM may overlap with the non-display area NDS (see, e.g., FIG. 3) of the display panel DP (see, e.g., FIG. 3) on a plane. The sealant SM together with the encapsulation substrate ES may block the exposure of a light-emitting element ED (see, e.g., FIG. 5) to external moisture and air. The sealant SM may include an organic adhesive or frit.

FIG. 3 illustrates a plan view of a display panel according to one or more embodiments of the present disclosure, FIG. 3 shows the layout relation of a wiring layer SGL and pixels PX, included in the display panel DP on a plane.

As shown in FIG. 3, the display panel DP may include a display area DA and a non-display area NDA. The display area DA may be an area in which a pixel PX, which will be explained later, is formed. The non-display area NDA may include a first non-display area NDA1 surrounding at least a portion of the display area DA and a second non-display area NDA2 overlapping with a pad area PA. In one or more embodiments, the first non-display area NDA1 may be defined along the border of the display area DA. The display area DA and the first non-display area NDA1 may define an active area AA. The second non-display area NDA2 may define the pad area PA.

The display panel DP may include a driving circuit GDC, multiple wirings SGL (hereinafter, wirings), multiple pads PD (hereinafter, pads) and multiple pixels PX (hereinafter, pixels). The pixels PX may be located in the display area DA. Each of the pixels PX may include an organic light-emitting diode and a pixel driving circuit connected therewith. The driving circuit GDC, the wirings SGL, and the pixel driving circuit may be included in a circuit element layer DP-CL, which will be explained later.

The driving circuit GDC may include a scanning driving circuit. The scanning driving circuit may produce multiple scanning signals (hereinafter, scanning signals), and may output the scanning signals to multiple scanning lines GL (hereinafter, scanning lines) in order. The scanning driving circuit may further output another control signal to the driving circuit of the pixels PX.

The scanning driving circuit may include multiple thin film transistors (hereinafter, transistors) formed through the same or substantially the same process as the driving circuit of the pixels PX, for example, a low temperature polycrystalline silicon (LTPS) process or a low temperature polycrystalline oxide (LTPO) process.

The wirings SGL may include scanning lines GL, data lines DL, a source line PL and a control signal line CSL. Each of the scanning lines GL may be connected with a respectively corresponding pixel PX among the pixels PX, and each of the data lines DL may be connected with a respectively corresponding pixel PX among the pixels PX. The control signal line CSL may provide the scanning driving circuit with control signals.

The wirings SGL may overlap with the display area DA, the first non-display area NDA1 and the second non-display area NDA2. The pads PD may be connected with corresponding wirings in the wiring layer SGL.

A line part may constitute most of the wirings SGL and connected with the pixel PX. The line part may be connected with the transistors of the pixel PX. The line part may have a single layer/multilayer structure, and the line part may have a single body (e.g., a single unitary/monolithic body) or may include two or more parts. The two or more parts may be located at different layers and may be connected with each other through one or more contact holes penetrating an insulation layer located between the two or more parts.

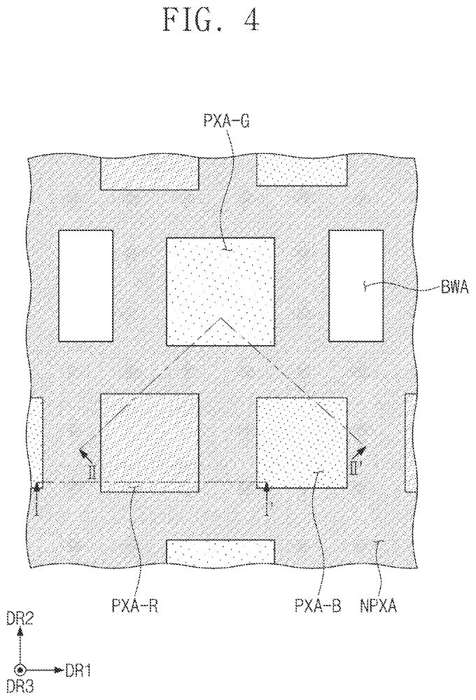

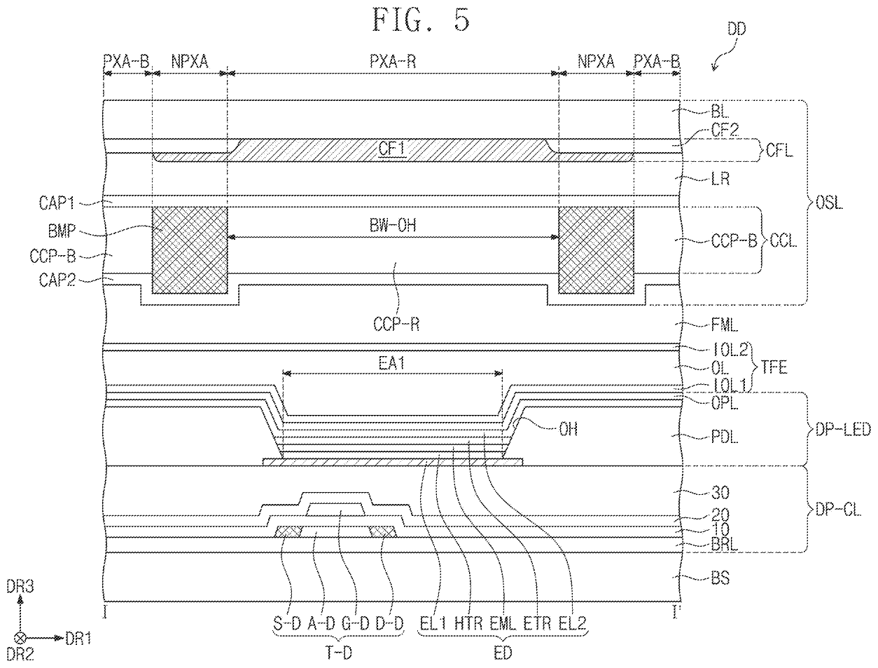

FIG. 4 illustrates an enlarged plan view of a portion of a display device according to one or more embodiments of the present disclosure. In FIG. 4, in the display device DD (see, e.g., FIG. 1A) according to one or more embodiments, a plane including three pixel areas PXA-R, PXA-B, and PXA-G, and adjacent bank well areas BWA is shown as an example. In one or more embodiments of the present disclosure, three pixel areas PXA-R, PXA-B, and PXA-G shown in FIG. 4 may be repeatedly arranged in the entire display area DA (see, e.g., FIG. 1A).

A non-light-emitting area NPXA may be located around (e.g., may surround) the first to third pixel areas PXA-R, PXA-B, and PXA-G. The non-light-emitting area NPXA may determine the boundaries of the first to third pixel areas PXA-R, PXA-B, and PXA-G. The non-light-emitting area NPXA may surround the first to third pixel areas PXA-R, PXA-B, and PXA-G. In the non-light-emitting area NPXA, a structure preventing or substantially reducing color mixing among the first to third pixel areas PXA-R, PXA-B, and PXA-G, such as a pixel definition layer PDL (see, e.g., FIG. 5) or a bank BMP (see, e.g., FIG. 5), may be located.

In FIG. 4, the first to third pixel areas PXA-R, PXA-B, and PXA-G, having the same or substantially the same shape on a plane and different areas on a plane are shown as an example, without limitation. At least two or more areas among the first to third pixel areas PXA-R, PXA-B and PXA-G may be the same or substantially the same. The areas of the first to third pixel areas PXA-R, PXA-B, and PXA-G may be determined according to the color of emitting light. The area of the pixel area emitting red light among primary colors may be the largest, and the area of the pixel area emitting blue light may be the smallest.

In FIG. 4, the first to third pixel areas PXA-R, PXA-B, and PXA-G, are shown to have a square shape, but the present disclosure is not limited thereto. For example, the first to third pixel areas PXA-R, PXA-B, and PXA-G may have a different polygonal shape (including substantially a polygon shape), such as a diamond and a pentagon on a plane. In one or more embodiments, the first to third pixel areas PXA-R, PXA-B, and PXA-G may have a rectangular shape with round corners (e.g., substantially a rectangular shape) on a plane.

In FIG. 4, the third pixel area PXA-G is located at the first row, and the first pixel area PXA-R and the second pixel area PXA-B are located at the second row, as an example. However, the present disclosure is not limited thereto, and the arrangement of the first to third pixel areas PXA-R, PXA-B, and PXA-G may be changed diversely. For example, the first to third pixel areas PXA-R, PXA-B, and PXA-G may be arranged at the same row.

Any one of the first to third pixel areas PXA-R, PXA-B, or PXA-G may provide a second light corresponding to source light, another one may provide a first light which is different from the second light, and the remaining one may provide a third light which is different from the first light and the second light. In one or more embodiments, the second pixel area PXA-B may provide the second light corresponding to the source light. In one or more embodiments, the first pixel area PXA-R may provide red light, the second pixel area PXA-B may provide blue light, and the third pixel area PXA-G may provide green light.

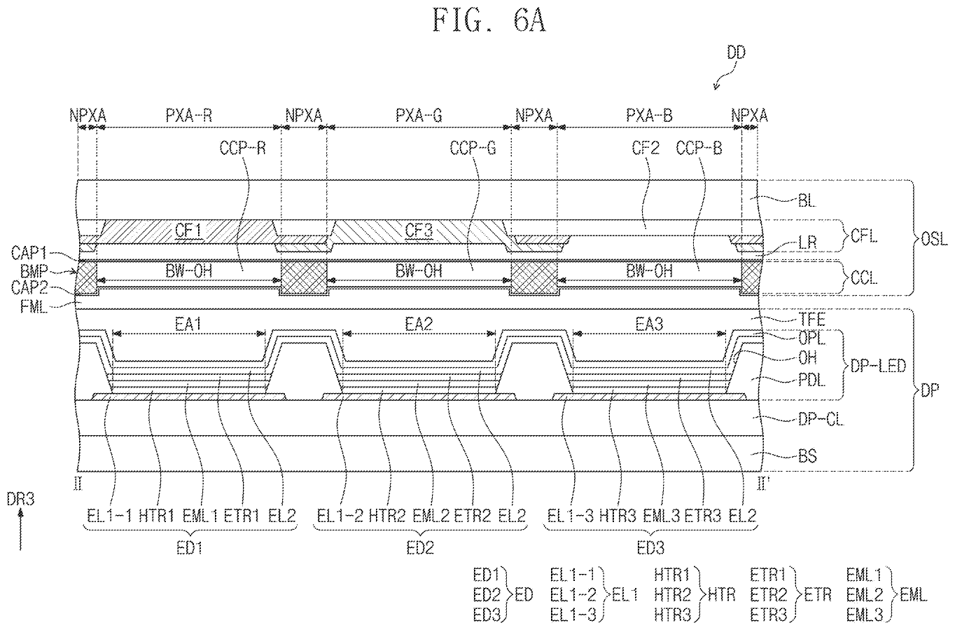

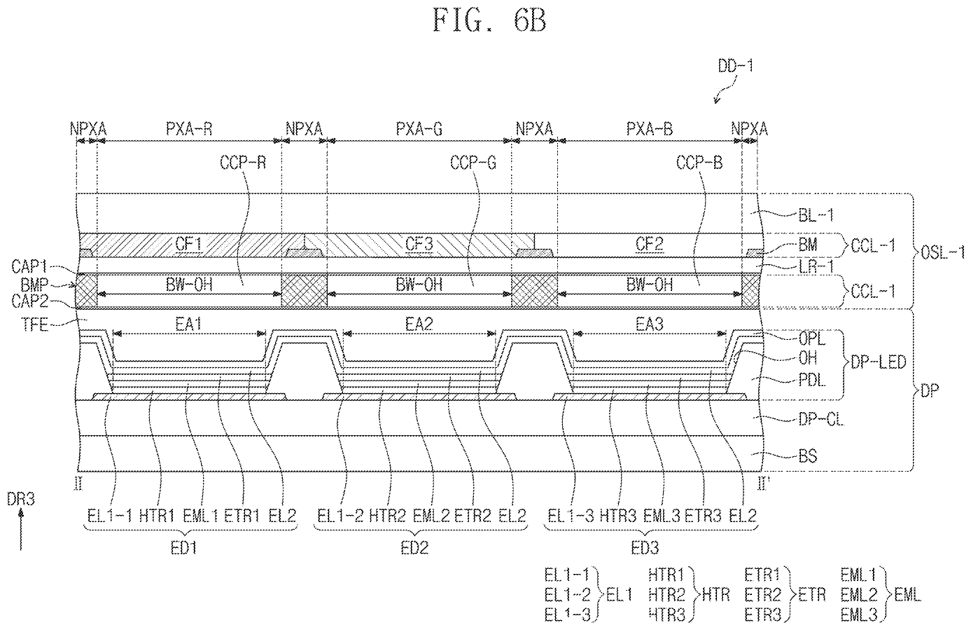

In the display area DA (see, e.g., FIG. 1A), a bank well area BWA may be defined. The bank well area BWA may be an area in which a bank well is formed for preventing or reducing defects due to mis-landing during the patterning process of multiple light control patterns CCP-R, CCP-B, and CCP-G (see FIG. 6A), included at a light control layer CCL (see FIG. 6A). The bank well may be a part receiving an incorrectly-applied forming material of light control patterns CCP-R, CCP-B, and CCP-G (see FIG. 6A) during the patterning process of the multiple light control patterns CCP-R, CCP-B, and CCP-G (see FIG. 6A). Through the bank well, defects induced during the forming process by the incorrectly-applied forming material of the light control patterns CCP-R, CCP-B, and CCP-G (see FIG. 6A) remaining on the bank BMP may be prevented or reduced. The bank well may be formed by removing a portion of the bank BMP. The bank well may be separately defined from a bank opening part BW-OH (see FIG. 6A) on a plane, in which multiple light control patterns CCP-R, CCP-B, and CCP-G (see FIG. 6A) are located. In FIG. 4, two bank well areas BWA are defined adjacent to the third pixel area PXA-G as an example. However, the present disclosure is not limited thereto, and the shape and arrangement of the bank well areas BWA may be changed in any suitable manner.

FIG. 5 illustrates a cross-sectional view of a display panel according to one or more embodiments of the present disclosure. FIG. 6A illustrates an enlarged diagram of a portion of the cross-section of a display panel according to one or more embodiments of the present disclosure. FIG. 5 illustrates a cross-sectional view of a light-emitting element included in the display panel according to one or more embodiments of the present disclosure. FIG. 5 illustrates a cross-sectional view corresponding to a line cut along the line I-I′ in FIG. 4. FIG. 6A shows a cross-sectional view corresponding to a line cut along the line II-II′ in FIG. 4.

Referring to FIG. 5, the display panel DP according to one or more embodiments may include a base substrate BS, a circuit element layer DP-CL located on the base substrate BS, and a display element layer DP-LED located on the circuit element layer DP-CL. In the description, the base substrate BS, the circuit element layer DP-CL and the display element layer DP-LED together may be referred to as a lower panel.

The base substrate BS may be a layer providing a base surface on which elements included at the circuit element layer DP-CL are located. In one or more embodiments, the base substrate BS may be a glass substrate, a metal substrate, a polymer substrate or the like. However, the present disclosure is not limited thereto, and the base substrate BS may be an inorganic layer, a functional layer or a composite material layer.

The base substrate BS may have a multilayer structure. For example, the base substrate BS may have a three-layer structure of a polymer resin layer, an adhesive layer and a polymer resin layer. Particularly, the polymer resin layer may include a polyimide-based resin. In addition, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin or a perylene-based resin. In the description, the “*-based” resin refers to a resin including a functional group of “*”.

The circuit element layer DP-CL may be located on the base substrate BS. The circuit element layer DP-CL may include a transistor T-D as a circuit element. According to the design of the driving circuit of the pixel PX (see FIG. 3), the configuration of the circuit element layer DP-CL may be changed, and one transistor T-D is shown as an example in FIG. 5. The layout relation of an active A-D, a source S-D, a drain D-D and a gate G-D, constituting the transistor T-D is shown as an example. The active A-D, the source S-D and the drain D-D may be areas divided according to the doping concentration or conductivity of a semiconductor pattern.

The circuit element layer DP-CL may include a lower buffer layer BRL, a first insulation layer 10, a second insulation layer 20 and a third insulation layer 30, located on the base substrate BS. For example, the lower buffer layer BRL, the first insulation layer 10 and the second insulation layer 20 may be inorganic layers, and the third insulation layer 30 may be an organic layer.

The display element layer DP-LED may include a light-emitting element ED as a display element. The light-emitting element ED may produce the above-described source light. The light-emitting element ED may include a first electrode EL1, a second electrode EL2 and an emission layer EML located therebetween. In one or more embodiments, the display element layer DP-LED may include an organic light-emitting diode as the light-emitting element. In one or more embodiments of the present disclosure, the light-emitting element may include a quantum dot light-emitting diode. For example, the emission layer EML included in the light-emitting element ED may include an organic light-emitting material as a light-emitting material, or the emission layer EML may include one or more quantum dots as the light-emitting material. Otherwise, in one or more embodiments, the display element layer DP-LED may include a subminiature light-emitting element which will be explained later, as the light-emitting element. The subminiature light-emitting element may include, for example, a micro-LED element and/or a nano-LED element. The subminiature light-emitting element may have a micro-or nano-scale size and may be a light-emitting element including an active layer located among multiple semiconductor layers.

A first electrode EL1 may be located on the third insulation layer 30. The first electrode EL1 may be an anode or a cathode. In addition, the first electrode EL1 may be a pixel electrode. The first electrode EL1 may be a transmissive electrode, a transflective electrode, or a reflective electrode. The first electrode EL1 may be directly or indirectly connected with the transistor T-D.

The display element layer DP-LED may include a pixel definition layer PDL. For example, the pixel definition layer PDL may be an organic layer. At the pixel definition layer PDL, a pixel opening part OH may be defined. The pixel opening part OH of the pixel definition layer PDL may expose at least a portion of the first electrode EL1. In this embodiment, a first light-emitting area EA1 may be defined by the pixel opening part OH.

On the first electrode EL1, an intermediate layer may be located. The intermediate layer may be located between the first electrode EL1 and the second electrode EL2. The intermediate layer may include at least one of a hole transport region HTR, an emission layer EML, or an electron transport region ETR. For example, as shown in FIG. 5, the intermediate layer may include a hole transport region HTR, an emission layer EML and an electron transport region ETR. The hole transport region HTR, the emission layer EML and the electron transport region ETR may be stacked in order in the third direction DR3 which is a thickness direction. For example, the intermediate layer may include the hole transport region HTR located on the first electrode EL1, the emission layer EML located on the hole transport region HTR, and the electron transport region ETR located on the emission layer EML.

The hole transport region HTR, the emission layer EML and the electron transport region ETR, included at the intermediate layer may overlap with at least the pixel area PXA-R. At least one of the hole transport region HTR, the emission layer EML, or the electron transport region ETR may be separately formed at each of the first to third pixel areas PXA-R, PXA-B, and PXA-G (see FIG. 6A). For example, as shown in FIG. 5, each of the hole transport region HTR, the emission layer EML and the electron transport region ETR may be patterned in the pixel opening part OH and formed separately at each of the first to third pixel areas PXA-R, PXA-B, and PXA-G (see FIG. 6A). In one or more embodiments, at least one of the hole transport region HTR, the emission layer EML, or the electron transport region ETR may be patterned and provided by an inkjet printing method. However, the present disclosure is not limited thereto, and each of the hole transport region HTR, the emission layer EML and the electron transport region ETR may be commonly disposed in (i.e., positioned in or located in) the first to third pixel areas PXA-R, PXA-B, and PXA-G (see, e.g., FIG. 6A). Each of the hole transport region HTR, the emission layer EML and the electron transport region ETR overlapping with the first to third pixel areas PXA-R, PXA-B and PXA-G (see, e.g., FIG. 6A) may have a single body (e.g., a single unitary/monolithic body).

The hole transport region HTR may include at least one of a hole injection layer, a hole transport layer, or an electron-blocking layer.

The emission layer EML may produce second light which is source light. The emission layer EML may produce blue light. The blue light may include light having a wavelength of about 410 nm to about 480 nm. The emission spectrum of the blue light may have the maximum peak in a wavelength region of about 440 nm to about 460 nm.

The electron transport region ETR may include at least one of an electron injection layer, an electron transport layer, or a hole blocking layer.

The second electrode EL2 may be located on the intermediate layer. As shown in FIG. 5, the second electrode EL2 may be located on the electron transport region ETR. The second electrode EL2 may be a cathode or an anode, but the present disclosure is not limited thereto. For example, if the first electrode EL1 is an anode, the second electrode EL2 may be a cathode, and if the first electrode EL1 is a cathode, the second electrode EL2 may be an anode. The second electrode EL2 may be a transmissive electrode, a transflective electrode, or a reflective electrode.

In one or more embodiments, the second electrode EL2 may be commonly located in the first to third pixel areas PXA-R, PXA-B, and PXA-G (see, e.g. FIG. 6A). The second electrode EL2 may overlap with the first to third pixel areas PXA-R, PXA-B, and PXA-G (see, e.g. FIG. 6A) and an adjacent non-light-emitting area NPXA. The second electrode EL2 overlapping with the first to third pixel areas PXA-R, PXA-B, and PXA-G may have a single body (e.g., a single unitary/monolithic body).

The display element layer DP-LED may further include an optical layer OPL. The optical layer OPL may be located on the light-emitting element ED. The optical layer OPL may be located on the second electrode EL2. The optical layer OPL may be located directly on the second electrode EL2. The optical layer OPL may be a layer for preventing or reducing the reflection of external light by the second electrode EL2 of the light-emitting element ED. The optical layer OPL may include multiple layers or a single layer. In one or more embodiments, the optical layer OPL may be an organic layer or an inorganic layer. In one or more embodiments, the optical layer OPL may have a refractive index of about 1.6 or more. The refractive index of the optical layer OPL with respect to light in a wavelength region of about 550 nm to 660 nm may be about 1.6 or more.

In one or more embodiments, the optical layer OPL may be commonly located in the first to third pixel areas PXA-R, PXA-B, and PXA-G (see, e.g. FIG. 6A). The optical layer OPL may overlap with the first to third pixel areas PXA-R, PXA-B, and PXA-G (see, e.g. FIG. 6A) and an adjacent non-light-emitting area NPXA. The optical layer OPL overlapping with the first to third pixel areas PXA-R, PXA-B, and PXA-G (see, e.g. FIG. 6A) may have a single body (e.g., a single unitary/monolithic body).

The display panel DP may include an encapsulation layer TFE protecting the second electrode EL2. The encapsulation layer TFE may be located on the pixel definition layer PDL to cover the light-emitting element ED. The encapsulation layer TFE may be located on the second electrode EL2, while filling a portion of the pixel opening part OH. In addition, as shown in FIG. 5, if the display element layer DP-LED includes the optical layer OPL, the encapsulation layer TFE may be located on the optical layer OPL. The encapsulation layer TFE may play the role of protecting the light-emitting element ED from moisture and/or oxygen, and protecting the light-emitting element ED from foreign materials, such as dust particles.

The encapsulation layer TFE may include an organic material or an inorganic material. The encapsulation layer TFE may have a multilayer structure in which an inorganic layer and an organic layer are repeated. In one or more embodiments, the encapsulation layer TFE may include a first inorganic layer IOL1, an organic layer OL, or a second inorganic layer IOL2. The first and second inorganic layers IOL1 and IOL2 may protect the light-emitting element ED from external moisture, and the organic layer OL may prevent the bad imprinting defects of the light-emitting element ED due to foreign materials injected during a manufacturing process. The display panel DP may further include a refractive index control layer on the encapsulation layer TFE for improving (e.g. increasing) light-emitting efficiency.

The inorganic layer included at the encapsulation layer TFE may include, for example, a silicon nitride layer, a silicon oxy nitride layer, a silicon oxide layer, a titanium oxide layer, or an aluminum oxide layer, and the present disclosure is not limited thereto. The organic layer included at the encapsulation layer TFE may include an acrylate-based organic film, but the present disclosure is not limited thereto.

As shown in FIG. 5, an optical structure layer OSL may be located on the encapsulation layer TFE. The optical structure layer OSL may include a light control layer CCL, a low refractive layer LR, a color filter layer CFL, and a base layer BL. The optical structure layer OSL may be referred to as an upper panel.

The optical control layer CCL may be located on the display element layer DP-LED including the light-emitting element ED. The optical control layer CCL may include a bank BMP, light control pattern CCP-R, light control pattern CCP-B, and a barrier layer CAP1.

The bank BMP may include a base resin and an additive. The base resin may be composed of diverse resin compositions which may be commonly referred to as binders. The additive may include a coupling agent and/or a photoinitiator. The additive may further include a dispersant.

The bank BMP may include a black coloring agent for blocking light. The bank BMP may include a black dye or a black pigment, blended with the base resin. In one or more embodiments, the black coloring agent may include carbon black, or a metal like chrome or the oxide thereof.

The bank BMP may include a bank opening part BW-OH corresponding to the pixel opening part OH. On a plane, the bank opening part BW-OH may overlap with the pixel opening part OH and have a larger area than the pixel opening part OH. For example, the bank opening part BW-OH may have an area greater than a light-emitting area EA1 defined by the pixel opening part OH. The term “corresponding” refers to the idea that two elements overlap when viewed from the thickness direction DR3 of the display panel DP and is not limited to the same area.

In the bank opening part BW-OH, light control patterns CCP-R and CCP-B may be located. At least a portion of the light control patterns CCP-R and CCP-B may change the optical properties of the source light. In one or more embodiments, a first light control pattern CCP-R may change the optical properties of the source light.

The first light control pattern CCP-R may include one or more quantum dots for changing the optical properties of the source light. The first light control pattern CCP-R may include one or more quantum dot for converting the source light into light having a different wavelength. In the first light control pattern CCP-R overlapping with the first pixel area PXA-R, the quantum dot may convert blue light which is the source light into red light.

“Quantum dot” refers to the crystal of a semiconductor compound. The quantum dot may emit light of various wavelengths according to the size of the crystal of the quantum dot. The quantum dot may emit light of various wavelengths by controlling an element ratio in the quantum dot compound.

The diameter of the quantum dot may be, for example, about 1 nm to about 10 nm.

The quantum dot may be synthesized by a chemical bath deposition, a metal organic chemical vapor deposition, a molecular beam epitaxy, or a similar process therewith.

The chemical bath deposition is a method of growing quantum dot particle crystal after mixing an organic solvent and a precursor material. During the growth of the crystal, the organic solvent naturally plays the role of a dispersant coordinated at the surface of the quantum dot crystal and may control the growth of the crystal. Accordingly, the chemical bath deposition may be more favorable than a vapor deposition method, such as a metal organic chemical vapor deposition (MOCVD) or a molecular beam epitaxy (MBE), and may control the growth of the quantum dot particle through a low-cost (e.g., lower-cost) process.

The core of the quantum dot may be selected from II-VI group compounds, III-V group compounds, III-VI group compounds, I-III-VI group compounds, IV-VI group compounds, IV group elements, IV group compounds, and combinations thereof.

The II-VI group compound may be selected from the group consisting of: a binary compound, such as CdSe, CdTe, CdS, ZnS, ZnSe, ZnTe, ZnO, HgS, HgSe, HgTe, MgSe, MgS and mixtures thereof; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a quaternary compound, such as HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The II-VI group semiconductor compound may further include I group metals and/or IV group elements. The I-II-V group compound may be selected from CuSnS or CuZnS, and the II-IV-VI group compound may select ZnSnS or the like. The I-II-IV-VI group compound may be selected from a quaternary compound selected from the group consisting of Cu₂ZnSnS₂, Cu₂ZnSnS₄, Cu₂ZnSnSe₄, Ag₂ZnSnS₂ and mixtures thereof.

The III-VI group compound may include: a binary compound, such as In₂S₃ or In₂Se₃; a ternary compound, such as InGaS₃ or InGaSe₃; or arbitrary combinations thereof.

The I-III-VI group compound may be selected from: a ternary compound, such as AgInS, AgInS₂, CuInS, CuInS₂, AgGaS₂, CuGaS₂ CuGaO₂, AgGaO₂, AgAlO₂ and mixtures thereof; or a quaternary compound, such as AgInGaS₂, and CulnGaS₂.

The III-V group compound may be selected from the group consisting of: a binary compound, such as GaN, GaP, GaAs, GaSb, AlN, AlP, AlAs, AlSb, InN, InP, InAs, InSb and mixtures thereof; a ternary compound, such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb and mixtures thereof; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof. The III-V group compound may further include a II group metal. For example, InZnP, and/or the like, may be selected as a III-II-V group compound.

The IV-VI group compound may be selected from the group consisting of: a binary compound, such as SnS, SnSe, SnTe, PbS, PbSe, PbTe and mixtures thereof; a ternary compound, such as SnSeS, SnSeTe, SnSTe, PbSeS, PbSeTe, PbSTe, SnPbS, SnPbSe, SnPbTe and mixtures thereof; and a quaternary compound, such as SnPbSSe, SnPbSeTe, SnPbSTe and mixtures thereof.

The II-IV-V group semiconductor compound may be a ternary compound selected from the group consisting of ZnSnP, ZnSnP₂, ZnSnAs₂, ZnGeP₂, ZnGeAs₂, CdSnP₂, CdGeP₂ and mixtures thereof.

The IV group element may be selected from the group consisting of Si, Ge and a mixture thereof. The IV group compound may be a binary compound selected from the group consisting of SiC, SiGe and a mixture thereof.

Each element included in a polynary compound, such as the binary compound, the ternary compound and the quaternary compound may be present at uniform concentration or non-uniform concentration in a particle. The chemical formulae refer to the types of elements included in the compound, and the element ratio in the compound may be different. For example, AgInGaS₂ may mean AgInₓGa₁₋ₓS₂ (x is a real number from 0 to 1).

For example, the binary compound, ternary compound, or quaternary compound may be present in a particle in a uniform concentration or may be present in the same particle in partially different concentration distribution. In addition, the quantum dot may have a core/shell structure in which one quantum dot encloses another quantum dot. The core/shell structure may have a concentration gradient of decreasing concentration of elements present in the shell toward the core.

In one or more embodiments, the quantum dot may have a core-shell structure including a core including the above-described nanocrystal and a shell surrounding the core. The shell of the quantum dot may be a protection layer for preventing or reducing the chemical deformation of the core to maintain semiconductor properties. The shell of the quantum dot may be a charging layer for imparting the quantum dot with electrophoresis characteristic. The shell may be a single layer or a multilayer. The shell of the quantum dot may include an oxide of a metal or nonmetal, a semiconductor compound, or a combination thereof.

For example, the metal or non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO; or a ternary compound, such as MgAl₂O₄, CoFe₂O₄, NiFe₂O₄ and/or CoMn₂O₄. However, the present disclosure is not limited thereto.

In addition, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and/or the like. However, the present disclosure is not limited thereto.

The quantum dot may have a full width of half maximum (FWHM) of emission wavelength spectrum of about 45 nm or less, about 40 nm or less, or about 30 nm or less. Within these ranges, color purity or color reproducibility may be improved (e.g. increased). Light emitted by a quantum dot is emitted in all directions, thus the light viewing angle may be expanded.

In addition, the shape of the quantum dot may be a commonly used shape in the art, without specific limitation. For example, the shape of the quantum dot may be spherical, pyramidal, multi-arm, or cubic nanoparticle, nanotube, nanowire, nanofiber, nanoplate particle, and/or the like.

Light of various wavelength bands may be obtained from a quantum dot emission layer by controlling the size of the one or more quantum dots and/or controlling an element ratio in the quantum dot compound. Accordingly, by using quantum dots having different sizes or by changing the element ratio in the quantum dot compound, a light-emitting element may emit light of varying wavelengths. For example, a quantum dot compound may be designed to emit red color, green color and/or blue color light by controlling the size of the quantum dot and/or by altering the element ratio of the quantum. For example, the quantum dots may be composed for emitting white light through the combination of light of various suitable colors.

In one or more embodiments, the quantum dot included in the first light control pattern CCP-R overlapping with the first pixel area PXA-R may have red light color. If the particle size of the quantum dot decreases, light in a short wavelength region may be emitted. For example, for quantum dots having the same core, the particle size of the quantum dot emitting green light may be smaller than the particle size of the quantum dot emitting red light. For example, for quantum dots having the same core, the particle size of the quantum dot emitting blue light may be smaller than the particle size of the quantum dot emitting green light. However, the present disclosure is not limited thereto, and for the quantum dots having the same core, the particle size may be controlled according to the material forming the shell and the thickness of the shell.

If the quantum dots have various suitable colors of light, such as blue, red and green, the quantum dots having different emitting colors may have different core materials.

The first light control pattern CCP-R may further include a scatterer. The first light control pattern CCP-R may include one or more quantum dots for converting blue light into red light and a scatterer scattering light.

The scatterer may include an inorganic particle. For example, the scatterer may include at least one of TiO₂, ZnO, Al₂O₃, SiO₂, and/or hollow silica. The scatterer may include one of TiO₂, ZnO, Al₂O₃, SiO₂, or hollow silica, or may be a mixture of two or more materials selected among TiO₂, ZnO, Al₂O₃, SiO₂, and/or hollow silica.

The first light control pattern CCP-R may include a base resin dispersing the quantum dots and the scatterer. The base resin is a medium in which the quantum dots and the scatterer are dispersed. The base resin may be composed of various suitable resin compositions which may be referred to as common binders. For example, the base resin may be an acrylate-based resin, a urethane-based resin, a silicon-based resin, an epoxy-based resin, and/or the like. The base resin may be a transparent resin.

In one or more embodiments, the first light control pattern CCP-R may be formed by an inkjet process. A liquid phase composition may be applied into the bank opening part BW-OH. The volume of a composition polymerized by a thermal curing process or a photocuring process may be reduced after curing.

Between the bottom of the bank BMP and the bottom of the first light control pattern CCP-R, a step may be formed. For example, the bottom of the bank BMP may be defined lower than the bottom of the first light control pattern CCP-R. The height difference between the bottom of the bank BMP and the bottom of the first light control pattern CCP-R may be, for example, about 2 μm to about 3 μm.

The light control layer CCL may include a barrier layer CAP1 located on one surface of the first light control pattern CCP-R. The barrier layer CAP1 may prevent or reduce the penetration of moisture and/or oxygen (hereinafter, referred to as “moisture/oxygen”). The barrier layer CAP1 may control a refractive index of the optical structure layer OSL. The barrier layer CAP1 may be located on one surface of the top or on one surface of the bottom of the first light control pattern CCP-R to block or reduce the exposure to moisture/oxygen of the first light control pattern CCP-R. For example, the barrier layer CAP1 may block or reduce the exposure to moisture/oxygen of the quantum dot included in the first light control pattern CCP-R. The barrier layer CAP1 may protect the first light control pattern CCP-R from external impact.

In one or more embodiments, the barrier layer CAP1 may be separate from the display element layer DP-LED, with the first light control pattern CCP-R therebetween. For example, the barrier layer CAP1 may be located on the top of the first light control pattern CCP-R. In one or more embodiments, the light control layer CCL may include an additional barrier layer CAP2 located between the first light control pattern CCP-R and the display element layer DP-LED. The barrier layer CAP1 may cover the top of the first light control pattern CCP-R adjacent to the low refractive layer LR. The additional barrier layer CAP2 may cover the bottom of the first light control pattern CCP-R adjacent to the display element layer DP-LED. The “top” may be a surface positioned on an upper part with respect to the third direction DR3, and the “bottom” may be a surface positioned on a lower part with respect to the third direction DR3.

In addition, the barrier layer CAP1 and the additional barrier layer CAP2 may cover the one surface of the bank BMP and cover the first light control pattern CCP-R.

The barrier layer CAP1 may cover the bank BMP adjacent to the low refractive layer LR and the one surface of the first light control pattern CCP-R. The barrier layer CAP1 may be located directly under the low refractive layer LR. The additional barrier layer CAP2 may be located below the step of the bank BMP and the first light control pattern CCP-R. The additional barrier layer CAP2 may be located directly on the filling layer FML.

The barrier layer CAP1 and the additional barrier layer CAP2 may include an inorganic material. In the display panel DP according to one or more embodiments, the barrier layer CAP1 may include silicon oxynitride SiON. Both the barrier layer CAP1 and the additional barrier layer CAP2 may include silicon oxynitride. However, the present disclosure is not limited thereto. For example, the barrier layer CAP1 located on the first light control pattern CCP-R may include silicon oxynitride, and the additional barrier layer CAP2 located under the first light control pattern CCP-R may include silicon oxide (SiOx). However, the present disclosure is not limited thereto.

A color filter layer CFL may be located on the light control layer CCL. The color filter layer CFL may include at least one color filter. The color filter may transmit (e.g., pass) light of a wavelength region and block light not in the wavelength region. The first color filter CF1 of the first pixel area PXA-R may transmit (e.g., pass) red light, and may block green light and blue light.

The first color filter CF1 may include a base resin and a dye and/or pigment dispersed in the base resin. The base resin may be a medium for dispersing the dye and/or pigment. The base resin may be composed of various suitable resin compositions which may be generally referred to as binders.

The first color filter CF1 may have a uniform thickness in the first pixel area PXA-R. Light converted from a source light of blue light into red light through the first light control pattern CCP-R may be provided outside with uniform luminance in the first pixel area PXA-R.

The optical structure layer OSL may include a low refractive layer LR. The low refractive layer LR may be located between the light control layer CCL and the color filter layer CFL. The low refractive layer LR may be located on the light control layer CCL, and may block or reduce the exposure of the first light control pattern CCP-R to moisture/oxygen. The low refractive layer LR may be located between the first light control pattern CCP-R and the first color filter CF1. and the low refractive layer LR may be of an optical functional layer improving (e.g. increasing) light extraction efficiency or preventing or substantially reducing the incidence of reflected light into the light control layer CCL. The low refractive layer LR may be a layer having a low refractive index compared to an adjacent layer.

The low refractive layer LR may include at least one inorganic layer. For example, the low refractive layer LR may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. However, the present disclosure is not limited thereto, and the low refractive layer LR may include an organic layer. For example, the low refractive layer LR may have a structure in which multiple hollow particles are dispersed in an organic polymer resin. The low refractive layer LR may be composed of a single layer or multiple layers.

In one or more embodiments, the display panel DP may further include a base layer BL located on the color filter layer CPL. The base layer BL may be a member providing a base surface on which a color filter layer CFL, a low refractive layer LR, and a light control layer CCL are located. The base layer BL may be a glass substrate, a metal substrate, a plastic substrate, or the like. However, the present disclosure is not limited thereto, and the base layer BL may be an inorganic layer, an organic layer or a composite material layer. In one or more embodiments, the base layer BL may be omitted.

An anti-reflection layer may be located on the base layer BL. The anti-reflection layer may be a layer reducing the reflectivity of external light incident from the outside. The anti-reflection layer may be a layer that selectively passes light emitted from the display panel DP. In one or more embodiments, the anti-reflection layer may be a single layer including a dye and/or pigment dispersed in a base resin. The anti-reflection layer may be provided as a continuous layer which entirely overlaps with the whole of the first to third pixel areas PXA-R, PXA-B, and PXA-F (see FIG. 4A).

A polarization layer may be omitted from the anti-reflection layer. Accordingly, light passed through the anti-reflection layer and incident to the display element layer DP-LED may be unpolarized light. The display element layer DP-LED may receive the unpolarized light from the upper part of the anti-reflection layer.

The display panel DP may include a lower panel including the display element layer DP-LED and an upper panel (optical structure layer OSL) including a light control layer CCL and a color filter layer CFL. In one or more embodiments, a filling layer FML may be located between the lower panel and the upper panel (OSL). In one or more embodiments, the filling layer FML may fill up a space between the display element layer DP-LED and the light control layer CCL. The filling layer FML may be located directly on the encapsulation layer TFE, and the additional barrier layer CAP2 may be located directly on the filling layer FML. The bottom of the filling layer FML may make contact with the top of the encapsulation layer TFE, and the top of the filling layer FML may make contact with the bottom of the additional barrier layer CAP2.

The filling layer FML may be a buffer between the display element layer DP-LED and the light control layer CCL. In one or more embodiments, the filling layer FML may play the absorb impact and increase the strength of the display panel DP. The filling layer FML may be formed from a filling resin including a polymer resin. For example, the filling layer FML may be formed from a filling layer resin including an acrylate-based resin or an epoxy-based resin.

The filling layer FML may be an element separated from the encapsulation layer TFE located thereunder and the additional barrier layer CAP2 located thereon, and may be formed by a separate process step. The filling layer FML may be formed using a material different from the encapsulation layer TFE and the additional barrier layer CAP2.

Referring to FIG. 6A, the display panel DP may include a base substrate BS and a circuit element layer DP-CL located on the base substrate BS. The circuit element layer DP-CL may be located on the base substrate BS. The circuit element layer DP-CL may include an insulation layer, a semiconductor pattern, a conductive pattern, and a signal line. The circuit element layer DP-CL may be obtained by forming an insulation layer, a semiconductor layer, and a conductive layer on the base substrate BS by a method, such as coating and deposition, and then, selectively pattering the insulation layer, the semiconductor layer and the conductive layer through multiple photolithography processes. Then, a semiconductor pattern, a conductive pattern, and a signal line, included at the circuit element layer DP-CL may be formed. In one or more embodiments, the circuit element layer DP-CL may include a transistor, a buffer layer, and multiple insulation layers.

The display element layer DP-LED may be located on the circuit element layer DP-CL. The display element layer DP-LED may include a pixel definition layer PDL and a light-emitting element ED.

The light-emitting element ED may include multiple light-emitting elements ED1, ED2, and ED3. Each of the light-emitting elements ED1, ED2, and ED3 may include a first electrode EL1, an intermediate layer, and a second electrode EL2, stacked in order in the third direction DR3. The intermediate layer may include at least one of a hole transport region HTR, an emission layer EML, or an electron transport region ETR. The first light-emitting element ED1 may include a first emission layer EML1 overlapping with the first pixel area PXA-R. The second light-emitting element ED2 may include a second emission layer EML2 overlapping with the second pixel area PXA-G. The third light-emitting element ED3 may include a third emission layer EML3 overlapping with the third pixel area PXA-B.

The pixel definition layer PDL may be located on the circuit element layer DP-CL. at the pixel definition layer PDL, preset pixel opening parts OH (see FIG. 5) may be defined. The pixel opening parts OH (see FIG. 5) defined at the pixel definition layer PDL may correspond to multiple pixel areas PXA-R, PXA-G, and PXA-B, respectively. A non-light-emitting area NPXA may be an area corresponding to the pixel definition layer PDL and adjacent to light-emitting areas PXA-R, PXA-G, and PXA-B. The non-light-emitting area NPXA may be an area.

The pixel definition layer PDL may include an organic resin and an inorganic material. For example, the pixel definition layer PDL may be formed by including a polyacrylate-based resin, a polyimide-based resin, silicon nitride (SiNx), silicon oxide (SiOx), silicon oxynitride (SiOxNy), and/or the like.

As shown in FIG. 6B, the hole transport region HTR, the emission layers EML1, EML2, and EML3, and the electron transport region ETR of the light-emitting elements ED1, ED2, and ED3 may be patterned and provided in the pixel opening part OH defined at the pixel definition layer PDL. In one or more embodiments, at least one of the hole transport region HTR, the emission layers EML1, EML2, and EML3, or the electron transport region ETR of the light-emitting elements ED1, ED2, and ED3 may be patterned and provided by an inkjet printing method. However, the present disclosure is not limited thereto, and at least one of the hole transport region HTR, the emission layers EML1, EML2, and EML3, and the electron transport region ETR of the light-emitting elements ED1, ED2, and ED3 may be provided as a common layer in the whole first to third pixel areas PXA-R, PXA-G, and PXA-B.

The pixel definition layer PDL may be located on the circuit element layer DP-CL and may cover a portion of the first electrode EL1. At the pixel definition layer PDL, a pixel opening part OH may be defined. The pixel opening part OH of the pixel definition layer PDL may expose at least a portion of the first electrode EL1. In one or more embodiments, light-emitting areas EA1, EA2, and EA3 are defined correspondingly to a portion of the area of the first electrode EL1 exposed by the pixel opening part OH.

The display element layer DP-LED may include a fist light-emitting area EA1, a second light-emitting area EA2, and a third light-emitting area EA3. The first light-emitting area EA1, the second light-emitting area EA2, and the third light-emitting area EA3 may be areas divided by the pixel definition layer PDL. The first light-emitting area EA1, the second light-emitting area EA2, and the third light-emitting area EA3 may correspond to the first pixel area PXA-R, the second pixel area PXA-G, and the third pixel area PXA-B, respectively.

The light-emitting areas EA1, EA2, and EA3 may overlap with the pixel areas PXA-R, PXA-B, and PXA-G, and may not overlap with the bank well area BWA. When viewed on a plane, the areas of the pixel areas PXA-R, PXA-B, and PXA-G, divided by the bank BMP may be greater than the areas of the light-emitting areas EA1, EA2, and EA3 divided by the pixel definition layer PDL.

In the light-emitting element ED, the first electrode EL1 may be located on the circuit element layer DP-CL. The first electrode EL1 may be an anode or a cathode. In addition, the first electrode EL1 may be a pixel electrode. The first electrode EL1 may be a transmissive electrode, a transflective electrode, or a reflective electrode.

The hole transport region HTR may be located between the first electrode EL1 and the emission layers EML1, EML2, and EML3. The hole transport region HTR may include at least one of a hole injection layer, a hole transport layer, or an electron-blocking layer. The hole transport region HTR may be patterned and provided to be separately located corresponding to each of the light-emitting areas EA1, EA2, and EA3. However, the present disclosure is not limited thereto, and the hole transport region HTR may be located as a common layer to overlap with the light-emitting areas EA1, EA2, and EA3 and the pixel definition layer PDL which divides the light-emitting areas EA1, EA2, and EA3.

The emission layers EML1, EML2, and EML3 may be located on the hole transport region HTR. In one or more embodiments, the emission layers EML1, EML2, and EML3 may be patterned and provided to be separately located corresponding to each of the light-emitting areas EA1, EA2, and EA3. In one or more embodiments, each of the first to third emission layers EML1, EML2, and EML3 may be located in the pixel opening part OH. For example, the first to third emission layers EML1, EML2, and EML3 may be separately formed to correspond to the light-emitting areas EA1, EA2, and EA3, which are divided by the pixel definition layer PDL. All the first to third emission layers EML1, EML2, and EML3, separately formed to correspond to the light-emitting areas EA1, EA2, and EA3, may emit blue light or light in different wavelength regions.

However, the present disclosure is not limited thereto, and the emission layers EML1, EML2, and EML3 may be provided as a common layer overlapping with the entire pixel definition layer PDL which divides the light-emitting areas EA1, EA2, and EA3. In one or more embodiments, the emission layer provided as a common layer in the light-emitting areas EA1, EA2, and EA3 may emit blue light.

The emission layers EML1, EML2, and EML3 may have a single layer formed using a single material, a single layer formed using multiple different materials, or a multilayer structure having multiple layers formed using multiple different materials. The emission layers EML1, EML2, and EML3 may include a fluorescent or phosphorescent material. In the light-emitting element according to one or more embodiments, the emission layers EML1, EML2, and EML3 may include an organic light-emitting material, a metal organic complex, or one or more quantum dots as a light-emitting material. In FIG. 5 and FIG. 6A, light-emitting elements ED1, ED2, and ED3, may include one emission layer are shown as an example. In one or more embodiments, the light-emitting element ED (see FIG. 5) may include multiple emission stacks including at least one light-emitting layer each. For example, the light-emitting element ED according to one or more embodiments may include a first electrode EL1, a second electrode EL2 located opposite the first electrode EL1, and multiple emission stacks located between the first electrode EL1 and the second electrode EL2. Between the multiple emission stacks, a charge generation layer may be located.

The emission layers EML1, EML2, and EML3, included in the light-emitting elements ED1, ED2, and ED3 may include an organic light-emitting material as a light-emitting material, or one or more quantum dots. The light-emitting elements ED1, ED2, and ED3 may further include a hole transport region HTR and an electron transport region ETR. The light-emitting elements ED1, ED2, and ED3 may further include a capping layer located on the second electrode EL2.

In one or more embodiments, the light-emitting elements ED1, ED2, and ED3 may emit light in a direction from the first electrode EL1 to the second electrode EL2, and on the basis of the emitting direction of light, the hole transport region HTR may be located under the emission layers EML1, EML2, and EML3, and the electron transport region ETR may be located on the emission layers EML1, EML2, and EML3. However, the present disclosure is not limited thereto, and the light-emitting elements ED1, ED2, and ED3 may have an inverted element structure in which the electron transport region ETR may be located under the emission layers EML1, EML2, and EML3, and the hole transport region HTR may be located on the emission layers EML1, EML2, and EML3 on the basis of the emitting direction of light.

Referring to FIG. 6A again, the electron transport region ETR may be located between the emission layers, EML1, EML2, and EML3, and the second electrode EL2. The electron transport region ETR may include at least one of an electron injection layer, an electron transport layer, or a hole blocking layer. Referring to FIG. 6A, the electron transport region ETR may be patterned and provided to be separately located corresponding to each of the light-emitting areas EA1, EA2, and EA3. However, the present disclosure is not limited thereto, and the electron transport region ETR may be a common layer to overlapping the whole of the light-emitting areas EA1, EA2, and EA3 and the pixel definition layer PDL which divides the light-emitting areas EA1, EA2, and EA3.

The second electrode EL2 may be provided on the electron transport region ETR. The second electrode EL2 may be a common electrode. The second electrode EL2 may be a cathode or an anode, but present disclosure is not limited thereto. For example, if the first electrode EL1 is an anode, the second electrode EL2 may be a cathode. For example, if the first electrode EL1 is a cathode, the second electrode EL2 may be an anode. The second electrode EL2 may be a transmissive electrode, a transflective electrode, or a reflective electrode.

The encapsulation layer TFE may be located on the light-emitting element ED. For example, in one or more embodiments, the encapsulation layer TFE may be located on the second electrode EL2. In addition, if the display element layer DP-LED includes an optical layer OPL, the encapsulation layer TFE may be located on the optical layer OPL. As described above, the encapsulation layer TFE may include at least one organic layer and at least one inorganic layer, and the inorganic layer and the organic layer may be alternately located.

The display device DD according to one or more embodiments may include an optical structure layer OSL located on the display element layer DP-LED. The optical structure layer OSL may include a light control layer CCL, a color filter layer CFL, and a base layer BL.

The light control layer CCL may include a light converter. The light converter may be one or more quantum dots or a phosphor. The light converter may convert the wavelength of provided light and emit. For example, the light control layer CCL may be a layer including one or more quantum dots in a partial portion or a layer including a phosphor in a partial portion.

The light control layer CCL may include multiple light control patterns CCP-R, CCP-B, and CCP-G. The light control patterns CCP-R, CCP-B, and CCP-G may be separated from each other. The light control patterns CCP-R, CCP-B, and CCP-G may be separated by a bank BMP. The light control patterns CCP-R, CCP-B, and CCP-G may be located in a bank opening part BW-OH defined in the bank BMP. However, the present disclosure is not limited thereto. In FIG. 4A, the bank BMP has a rectangular shape on a cross-sectional view and does not overlap with the light control patterns CCP-R, CCP-B, and CCP-G, but the edge of light control patterns CCP-R, CCP-B, and CCP-G may overlap with at least a portion of the bank BMP. The bank BMP may have a trapezoidal shape on a cross-sectional view. The bank BMP may have an increasing width on a cross-sectional view if the bank BMP gets closer to the display element layer DP-LED.

The light control patterns CCP-R, CCP-B, and CCP-G may convert the wavelength of light provided from the display element layer DP-LED or transmit the light provided. The light control patterns CCP-R, CCP-B, and CCP-G may be formed by an inkjet process. A liquid-phase ink composition may be applied into the bank opening part BW-OH. The applied ink composition may be polymerized by a thermal curing process or a photocuring process to form the light control patterns CCP-R, CCP-B, and CCP-G.

The light control layer CCL may include a first light control pattern CCP-R including a first quantum dot converting source light provided from the light-emitting element ED to first light, a second light control pattern CCP-B transmitting the source light, and a third light control pattern CCP-G including a second quantum dot converting the source light into second light.

In one or more embodiments, the first light control pattern CCP-R may provide red light which is the first light, and the second light control pattern CCP-B may transmit and provide blue light which is the source light provided from the light-emitting element ED. The third light control pattern CCP-G may provide green light which is the second light. For example, the first quantum dot may be a red quantum dot, and the second quantum dot may be a green quantum dot.

In addition, the light control layer CCL may further include a scatterer. The first light control pattern CCP-R may include the first quantum dot and the scatterer, the third light control pattern CCP-G may include the second quantum dot and the scatterer, and the second light control pattern CCP-B may not include the quantum dot and may include the scatterer.

Each of the first light control pattern CCP-R, the second light control pattern CCP-B, and the third light control pattern CCP-G may include a base resin for dispersing the quantum dots and the scatterer. In one or more embodiments, the first light control pattern CCP-R may include the first quantum dots and the scatterer dispersed in the base resin. In one or more embodiments, the third light control pattern CCP-G may include the second quantum dots and the scatterer dispersed in the base resin. In one or more embodiments, the second light control pattern CCP-B may include the scatterer dispersed in the base resin.

The light control layer CCL may include a barrier layer CAP1 located on one surface of the light control pattern. The light control layer CCL may include a barrier layer CAP1 separated from the display element layer DP-LED with the light control pattern CCP-R therebetween and an additional barrier layer CAP2 adjacent to the display element layer DP-LED.

In the display panel DP, the optical structure layer OSL may include a color filter layer CFL located on the light control layer CCL. The color filter layer CFL may include color filters CF1, CF2, and CF3. The color filter layer CFL may include a first color filter CF1 transmitting the first light, a second color filter CF2 transmitting the source light, and a third color filter CF3 transmitting the second light. In one or more embodiments, the first color filter CF1 may be a red filter, the second color filter CF2 may be a blue filter, and the third color filter CF3 may be a green filter.

Each of the filters CF1, CF2, and CF3 may include a polymer photosensitive resin and a colorant. The first color filter CF1 may include a red colorant, the second color filter CF2 may include a blue colorant, and the third color filter CF3 may include a green colorant. The first color filter CF1 may include a red pigment or a red dye, the second color filter CF2 may include a blue pigment or a blue dye, and the third color filter CF3 may include a green pigment or a green dye.

The first to third color filters CF1, CF2, and CF3 may be correspondingly located in the first pixel area PXA-R, the second pixel area PXA-G and the third pixel area PXA-B, respectively. In addition, the first to third color filters CF1, CF2, and CF3 may be correspondingly disposed to the first light control pattern to the third light control pattern CCP-R, CCP-B, and CCP-G, respectively.

In addition, corresponding to the non-light-emitting area NPXA located among the pixel areas PXA-R, PXA-B, and PXA-G, multiple color filters CF1, CF2, and CF3 transmitting different light may be overlapped and positioned. Multiple color filters CF1, CF2, and CF3 may be overlapped and positioned in the third direction DR3 which is the thickness direction to divide the boundaries among the adjacent pixel areas PXA-R, PXA-B. and PXA-G. The color filter layer CFL may include a light blocking part for dividing the boundaries among adjacent color filters CF1, CF2, and CF3. The light blocking part may be formed as a blue filter or formed by including an organic light blocking material or an inorganic light blocking material, including a black pigment or a black dye.

The optical structure layer OSL may include a low refractive layer LR located between the light control layer CCL and the color filter layer CFL. The low refractive layer LR may be located between the light control patterns, CCP-R, CCP-B, and CCP-G, and the color filters, CF1, CF2, and CF3. The low refractive layer LR may be located on the light control layer CCL to block the exposure of the light control patterns CCP-R, CCP-B, and CCP-G to moisture/oxygen. In addition, the low refractive layer LR may be located between the light control patterns, CCP-R, CCP-B, and CCP-G, and the color filters, CF1, CF2, and CF3, to play the role of an optical functional layer improving (e.g. increasing) light extraction efficiency or preventing or substantially reducing the incidence of reflected light to the light control layer CCL. The low refractive layer LR may be a layer having a low refractive index compared to adjacent other layers.

The low refractive layer LR may include at least one inorganic layer. For example, the low refractive layer LR may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. However, the present disclosure is not limited thereto, and the low refractive layer LR may include an organic film. For example, the low refractive layer LR may have a structure in which multiple hollow particles are dispersed in an organic polymer resin. The low refractive layer LR may be composed of a single layer or multiple layers.

In one or more embodiments, the optical structure layer OSL may further include a base layer BL located on the color filter layer CFL. The base layer BL may be a member providing a base surface on which the color filter layer CFL and the light control layer CCL are located. The base layer BL may be a glass substrate, a metal substrate, a plastic substrate, or the like. However, the present disclosure is not limited thereto, and the base layer BL may be an inorganic layer, an organic layer, or a composite material layer. In one or more embodiments, the base layer BL may be omitted.

FIG. 6B illustrates an enlarged diagram of a partial region of a partial area in the cross-section of a display device according to one or more embodiments of the present disclosure. FIG. 6B shows a cross-section corresponding to a cutting line II-II′ in FIG. 4. FIG. 6B shows a display device DD-1 according to one or more other embodiments, which is different from the display device DD shown in FIG. 6A.

Referring to FIG. 6B, the display device DD-1 according to one or more embodiments may include a lower panel including a base substrate BS, a circuit element layer DP-CL located on the base substrate BS, a display element layer DP-LED located on the circuit element layer DP-CL, and an optical structure layer OSL-1 located on the lower panel. In the display device DD-1 according to one or more embodiments, the optical structure layer OSL-1 may include a light control layer CCL-1, a low refractive layer LR-1, a color filter layer CFL, and a base layer BL-1, stacked in order on an encapsulation layer TFE. The optical structure layer OSL-1 may include a barrier layer CAP1 and an additional barrier layer CAP2, located on and under the light control layer CCL-1.

The light control layer CCL-1 may be located on the display element layer DP-LED and the encapsulation layer TFE with the additional barrier layer CAP2 therebetween. The light control layer CCL-1 may include multiple banks BMP and light control patterns CCP-B, CCP-G, and CCP-R, located among the banks BMP. On the light control layer CCL-1, a low refractive layer LR may be located.

The color filter layer CFL may include multiple color filters, CF1, CF2, and CF3, and a light blocking part BM.

Compared to the display device DD shown in FIG. 6A, the display device DD-1 according to one or more embodiments, shown in FIG. 6B, is a display device in which the light control layer CCL-1, the low refractive layer LR, and the color filter layer CFL are positioned with the top of the encapsulation layer TFE as a base surface. For example, the light control patterns CCP-R, CCP-G, and CCP-R of the light control layer CCL-1 may be formed on the encapsulation layer TFE by a continuous process. The color filters, CF1, CF2, and CF3, of the color filter layer CFL may be formed in order on the light control layer CCL-1 through a continuous process. The light control layer CCL-1 may be formed on the top of the additional barrier layer CAP2 located on the encapsulation layer TFE, as a base surface, and may have an up and down inverted shape of the shape of the light control layer CCL shown in FIG. 6A. Multiple banks BMP and multiple light control patterns CCP-B, CCP-G, and CCP-R may have an up and down inverted shape of the shape shown in FIG. 6A. The color filter layer CFL may be formed with the light control layer CCL-1 as a base surface and may have a shape different from FIG. 6A.

In the color filter layer CFL according to one or more embodiments, a light blocking part BM may be a black matrix. The light blocking part BM may be formed by including an organic light blocking material or an inorganic light blocking material, including a black pigment or a black dye. The light blocking part BM may prevent light leakage and divide the boundaries among adjacent color filters CF-B, CF-G, and CF-R.

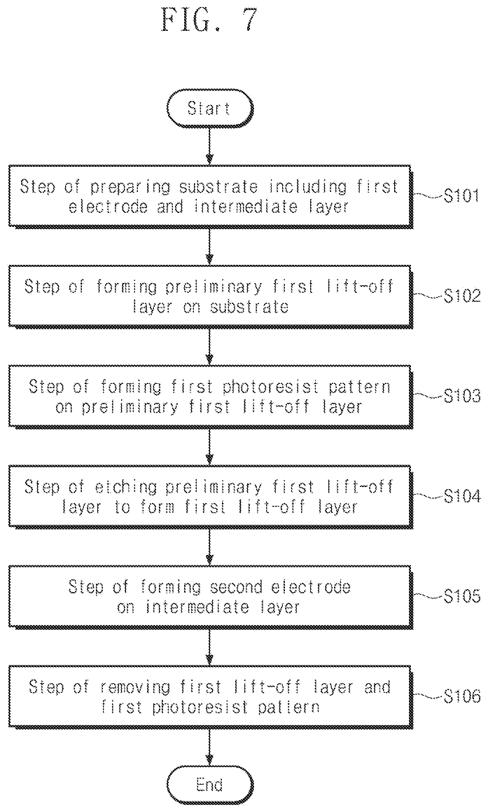

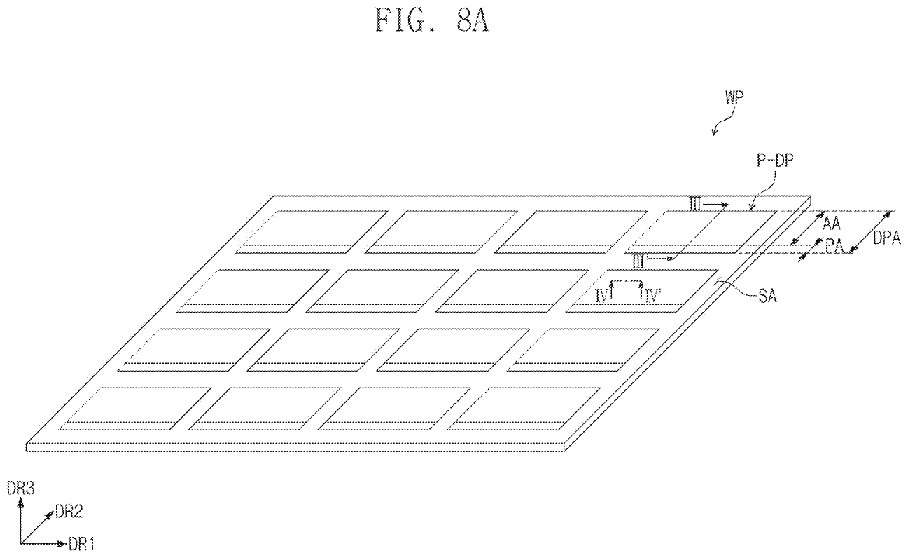

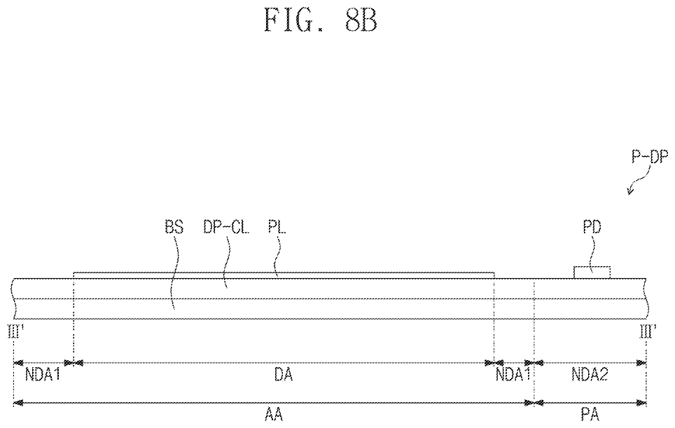

FIG. 7 illustrates a flowchart showing a method for manufacturing a display device according to one or more embodiments. Referring to FIG. 7, the method for manufacturing a display device according to one or more embodiments of the present disclosure may include a step of preparing a substrate (S101), a step of forming a preliminary first lift-off layer on the substrate (S102), a step of forming a first photoresist pattern having a photo-opening part overlapping with a display area, on the preliminary first lift-off layer (S103), a step of etching the preliminary first lift-off layer to form a first lift-off layer exposing the display area (S104), a step of forming a second electrode on the intermediate layer through the photo-opening part (S105), and a step of removing the first lift-off layer and the first photoresist pattern (S106).

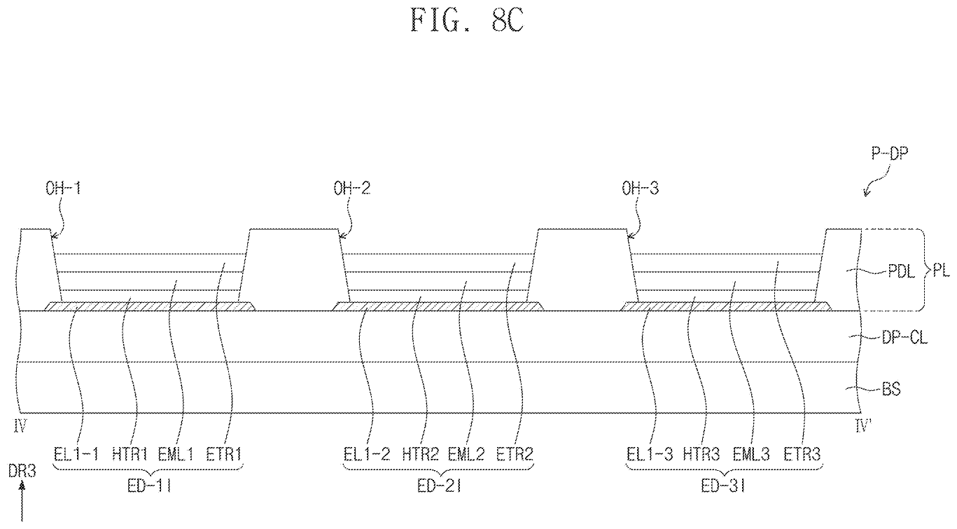

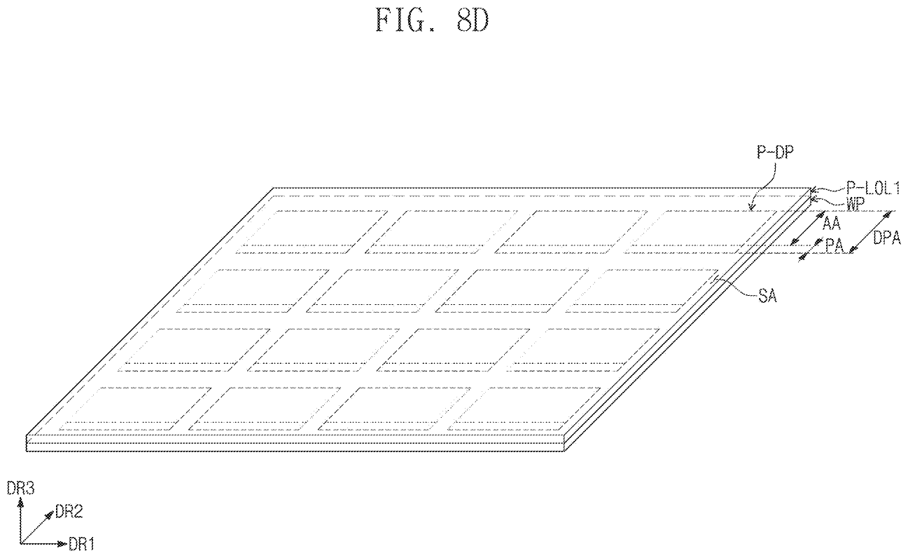

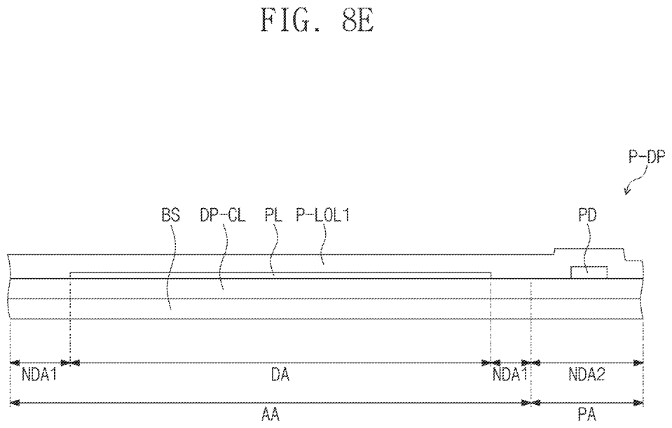

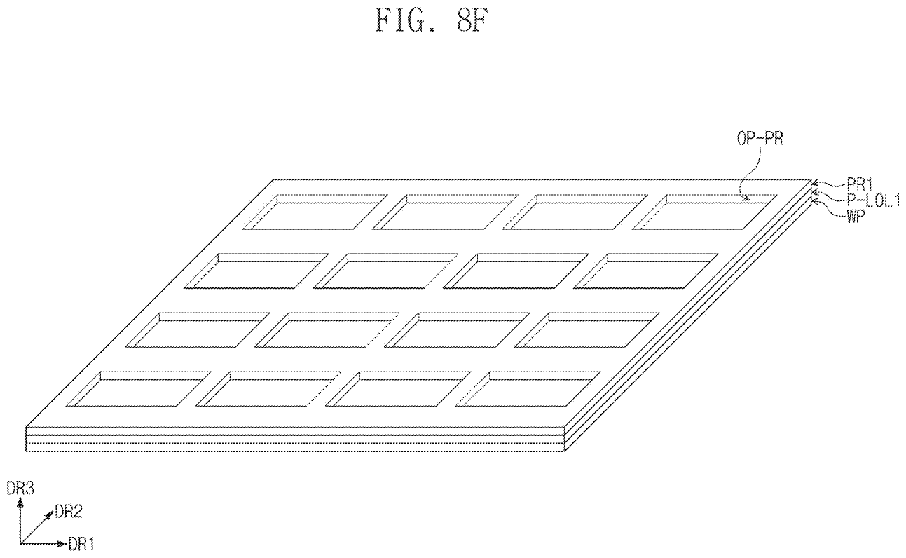

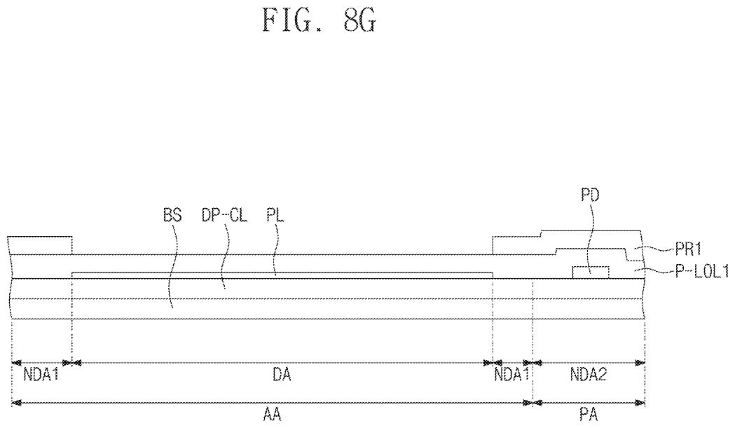

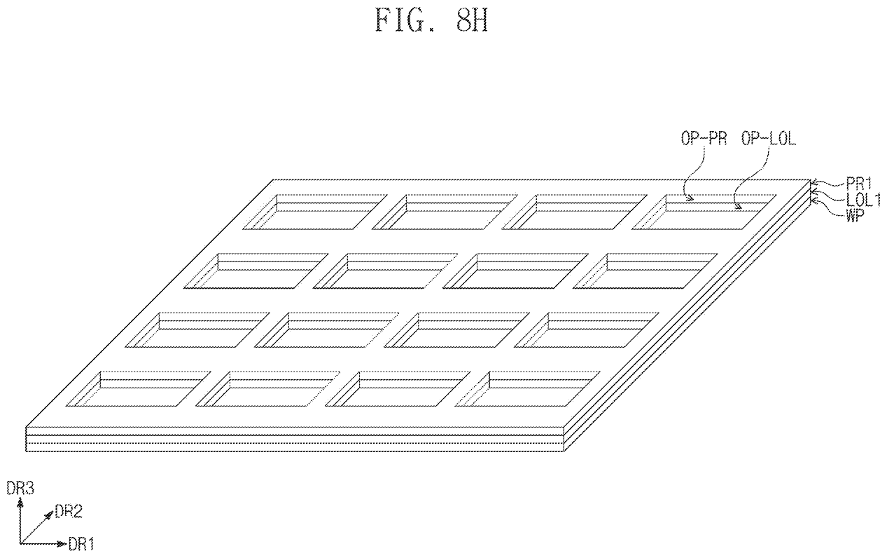

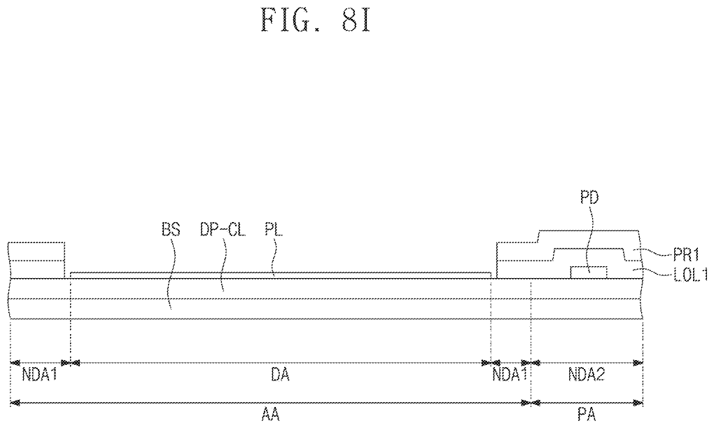

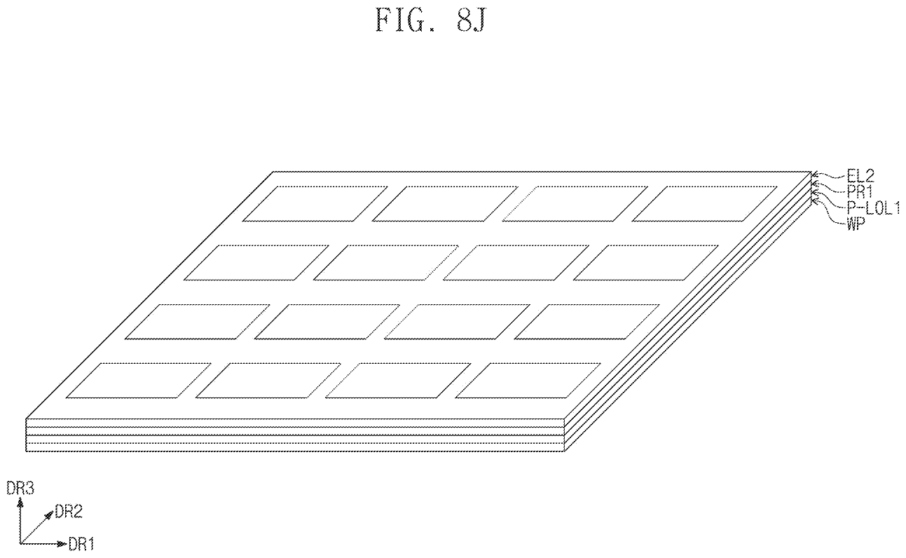

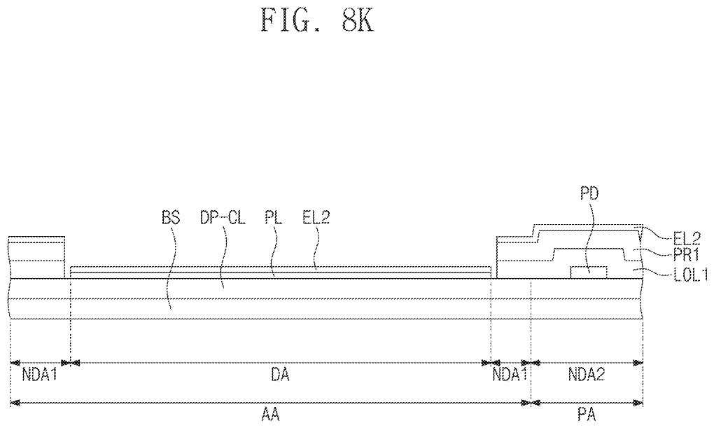

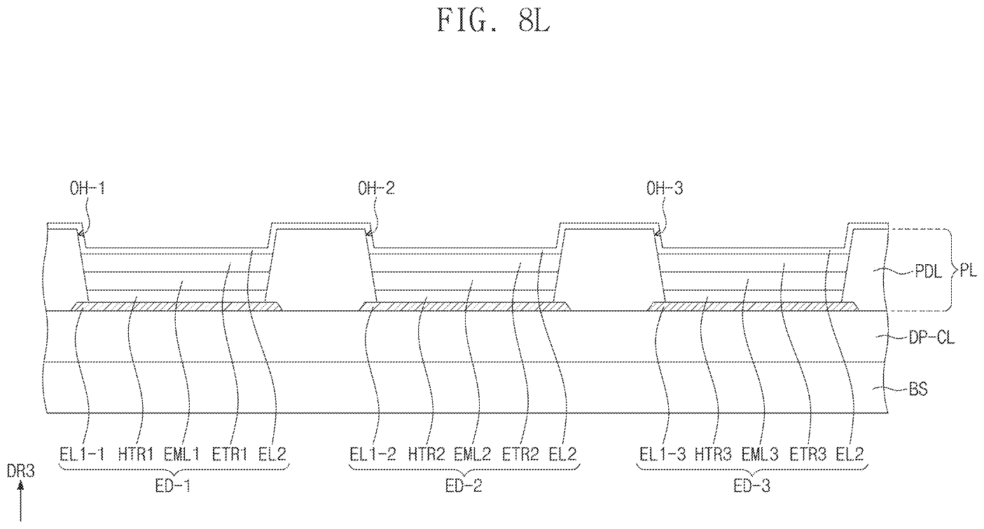

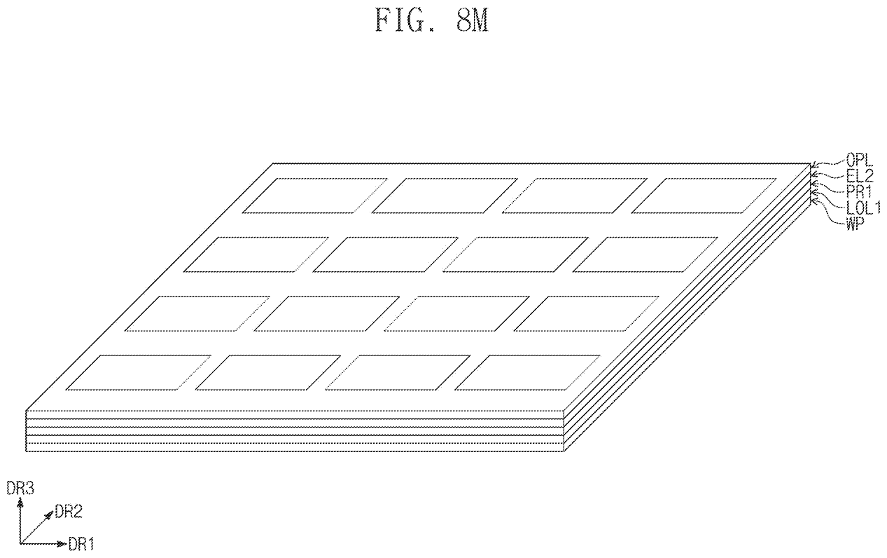

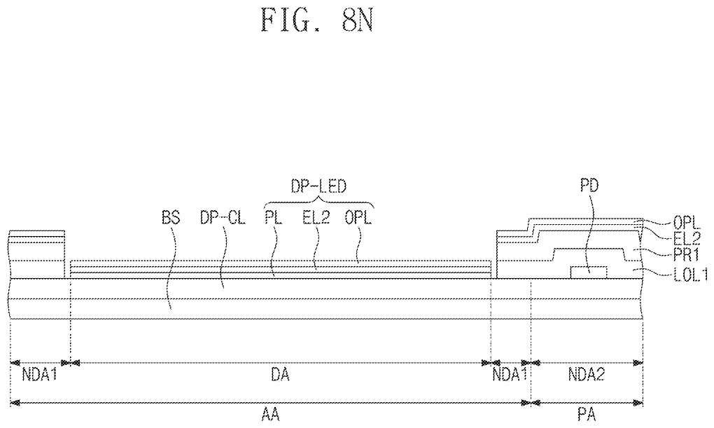

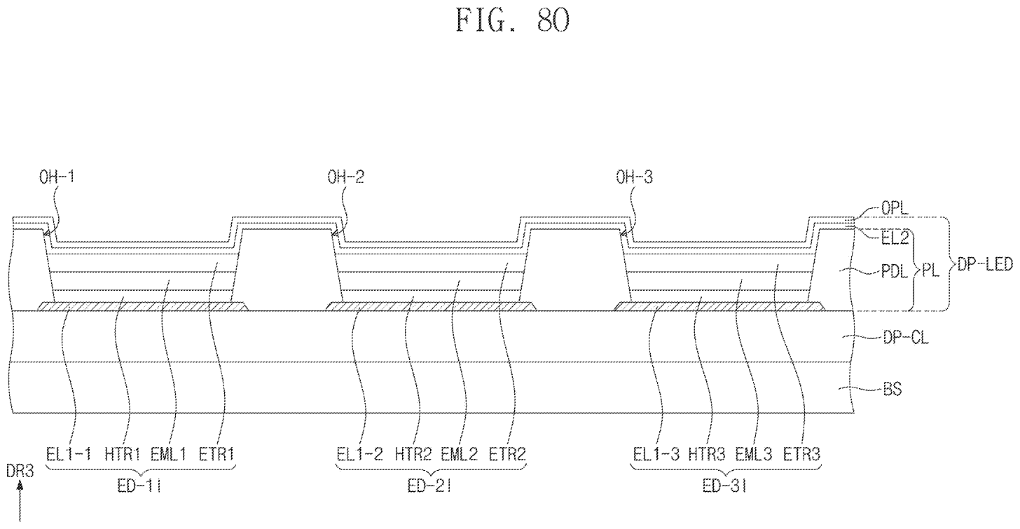

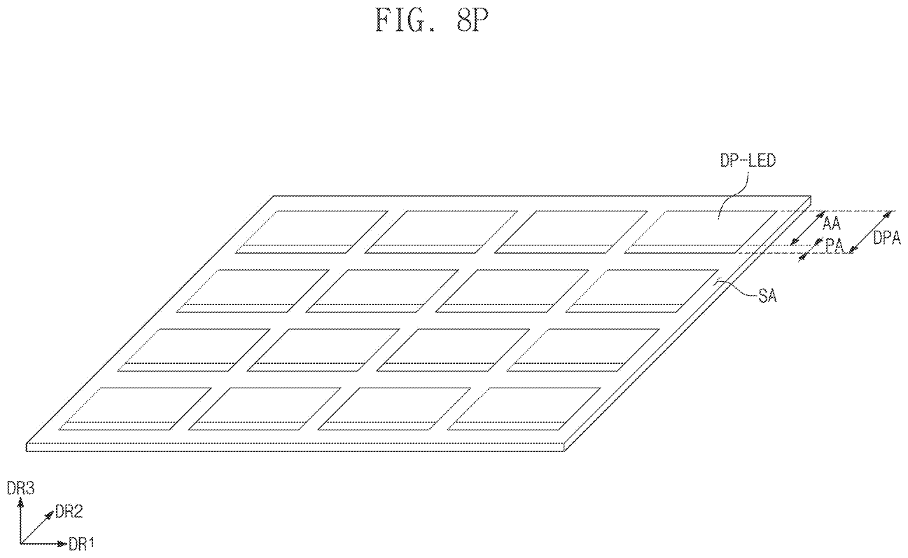

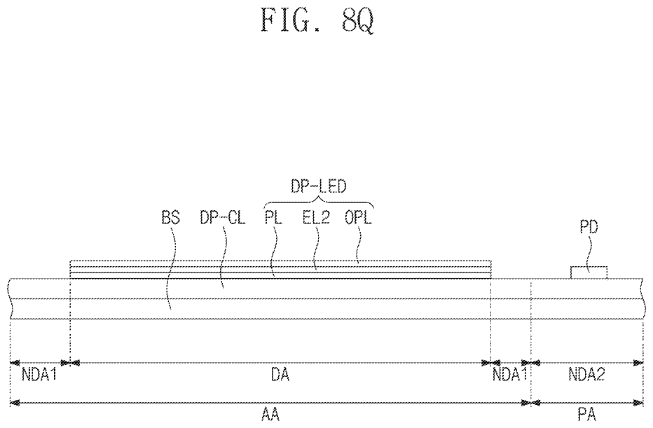

FIGS. 8A to FIG. 8Q illustrate cross-sectional views showing some steps of the method for manufacturing a display device according to one or more embodiments of the present disclosure. FIG. 8A, FIG. 8D, FIG. 8F, FIG. 8H, FIG. 8J, FIG. 8M, and FIG. 8P illustrate perspective views of the method for manufacturing a display device according to one or more embodiments of the present disclosure. FIG. 8B, FIG. 8C, FIG. 8E, FIG. 8G, FIG. 8I, FIG. 8K, FIG. 8L, FIG. 8N, FIG. 8O, and FIG. 8Q illustrate cross-sectional views of the method for manufacturing a display device according to one or more embodiments of the present disclosure. FIG. 8B, FIG. 8E, FIG. 8G, FIG. 81, FIG. 8K, FIG. 8N, and FIG. 8Q illustrate cross-sectional views showing the method for manufacturing a display device in order on cross-sections taken along the line III-III′ in FIG. 8A. FIG. 8C, FIG. 8L, and FIG. 80 illustrate cross-sectional views showing some steps of the method for manufacturing a display device on cross-sections taken along the line IV-IV′ in FIG. 8A.

A display device manufactured by the method for manufacturing a display device according to one or more embodiments, explained referring to FIG. 8A to FIG. 8Q may have the structure of the display device according to one or more embodiments, explained referring to FIG. 1 to FIG. 6B. Accordingly, in the explanation on the method for manufacturing a display device according to one or more embodiments of the present disclosure, referring to FIG. 8A to FIG. 8Q, the same elements as the elements of the display device of FIG. 1 to FIG. 6B will be designated by the same reference symbols, and the explanation on overlapping parts will be omitted.

Referring to FIG. 8A to FIG. 8C, the method for manufacturing a display device according to one or more embodiments of the present disclosure may include a step of preparing a substrate WP.

FIG. 8A illustrates a diagram showing the step of providing the substrate WP according to one or more embodiments of the present disclosure. As shown in FIG. 8A, the substrate WP may be a mother glass substrate having a large area. For example, the substrate WP may be a mother substrate used for the manufacture of multiple display devices at the same or substantially the same time. Referring to FIG. 8A, multiple first preliminary display panels P-DP may be formed in the substrate WP. The substrate WP may be a mother substrate having a size on which the multiple first preliminary display panels P-DP may be formed. The first preliminary display panels P-DP may be separately arranged on a plane.

The substrate WP may include a display unit area DPA in which multiple first preliminary display panels P-DP are formed, and a peripheral area SA other than the display unit area DPA. The display unit area DPA of the substrate WP may be an area on which the first preliminary display panels P-DP are formed. The display unit area DPA of the substrate WP may be an area on which multiple display panels are formed by depositing, patterning, thin-film forming, and etching processes. Multiple display panels may be provided at the same or substantially the same time by the same or substantially the same processes.

The display unit area DPA of the substrate WP may include an active area AA and a pad area PA adjacent to the active area AA. The active area AA of the substrate WP may correspond to the active area AA shown in FIG. 3, and the pad area PA of the substrate WP may correspond to the pad area PA shown in FIG. 3. Referring to FIG. 3, FIG. 8A and FIG. 8B, the first preliminary display panels P-DP may include pads PD correspondingly formed in the pad area PA. Referring to FIG. 3 and FIG. 8B, the active area AA may include a display area DA and a first non-display area NDA1 surrounding the display area DA. The display area DA may be an area corresponding to an area on which a light-emitting element is formed. The display area DA, the first non-display area NDA1, and the second non-display area NDA2 of the substrate WP respectively may correspond to the display area DA, the first non-display area NDA1, the second non-display area NDA2 of the display panel DP, shown in FIG. 3.

Referring to FIG. 8A and FIG. 8C, the first preliminary display panel P-DP may be defined as elements in a step prior to forming the second electrode EL2, the optical layer OPL (see FIG. 8M), and the encapsulation layer TFE (see FIG. 6B), with the elements included in the display panel DP explained in FIG. 6A and FIG. 6B. The first preliminary display panel P-DP may include the same or substantially the same elements as those of the above-described display panel P-DP except for the second electrode EL2, the optical layer OPL (see FIG. 8M), and the encapsulation layer TFE (see FIG. 6B). The first preliminary display panel P-DP may include a base substrate BS, a circuit element layer DP-CL, first electrodes EL1-1, EL1-2, and EL1-3, and an intermediate layer. The intermediate layer may include at least one of hole transport regions HTR1, HTR2, and HTR3; emission layers EML1, EML2, and EML3; or electron transport regions ETR1, ETR2, and ETR3. For example, as shown in FIG. 8C, the intermediate layer may include the hole transport regions HTR1, HTR2, and HTR3, the emission layers EML1, EML2, and EML3, and the electron transport regions ETR1, ETR2, and ETR3.

Referring to FIG. 8C, the first preliminary display panel P-DP may include a base substrate BS, a circuit element layer DP-CL located on the base substrate BS, and a preliminary display element layer PL located on the circuit element layer DP-CL. The preliminary display element layer PL may include a pixel definition layer PDL located on the circuit element layer DP-CL and preliminary light-emitting elements ED-11, ED-21, and ED-31. Pixel opening parts OH-1, OH-2, and OH-3 respectively corresponding to the first to third pixel areas PXA-R, PXA-G, and PXA-B may be defined at the pixel definition layer PDL, as described in FIG. 4 and FIG. 6A. The first pixel opening part OH-1 may be defined in correspondence to the first pixel area PXA-R (see FIG. 6A and FIG. 6B), the second pixel opening part OH-2 may be defined in correspondence to the second pixel area PXA-G (see FIG. 6A and FIG. 6B), and the third pixel opening part OH-3 may be defined in correspondence to the third pixel area PXA-B (see FIG. 6A and FIG. 6B).

The first to third preliminary light-emitting elements ED-11, ED-21, and ED-31 may be located in the first to third pixel opening parts OH-1, OH-2, and OH-3, respectively. A preliminary display element layer PL may include a first preliminary light-emitting element ED-11 located in the first pixel opening part OH-1, a second preliminary light-emitting element ED-21 located in the second pixel opening part OH-2, and a third preliminary light-emitting element ED-31 located in the third pixel opening part OH-3. The first preliminary light-emitting element ED-11 may include a first sub electrode EL1-1, a first hole transport region HTR1, a first emission layer EML1, and a first electron transport region ETR1, stacked in order along the third direction DR3. The second preliminary light-emitting element ED-21 may include a second sub electrode EL1-2, a second hole transport region HTR2, a second emission layer EML2, and a second electron transport region ETR2, stacked in order along the third direction DR3. The third preliminary light-emitting element ED-31 may include a third sub electrode EL1-3, a third hole transport region HTR3, a third emission layer EML3, and a third electron transport region ETR3, stacked in order along the third direction DR3.

In FIG. 8A to FIG. 8Q, the hole transport regions HTR1, HTR2 and HTR3, the emission layers EML1, EML2 and EML3, and the electron transport regions ETR1, ETR2 and ETR3, respectively included in the preliminary light-emitting elements ED-11, ED-21, and ED-31, are separately formed to correspond to the pixel opening parts OH-1, OH-2 and OH-3, but one or more embodiments of the present disclosure is not limited thereto. For example, at least one of the hole transport regions HTR1, HTR2, and HTR3; the emission layers EML1, EML2, and EML3; or the electron transport regions ETR1, ETR2, and ETR3 may be located in the pixel opening parts OH-1, OH-2, and OH-3, and may be provided as a common layer having a single body (e.g., a single unitary/monolithic body) on the pixel definition layer PDL.

Referring to FIG. 8D and FIG. 8E, the method for manufacturing a display device according to one or more embodiments of the present disclosure may include a step of forming a preliminary first lift-off layer P-LOL1 on the substrate WP.

The preliminary first lift-off layer P-LOL1 may be provided on the first preliminary display panel P-DP. The preliminary first lift-off layer P-LOL1 may entirely overlap with the first preliminary display panel P-DP. As shown in FIG. 8D and FIG. 8E, the preliminary first lift-off layer P-LOL1 may be provided to overlap with the active area AA, the pad area PA, and the peripheral area SA of the substrate WP. Referring to FIG. 3, FIG. 8D and FIG. 8E, the preliminary first lift-off layer P-LOL1 may cover pads PD located in the pad area PA. The preliminary first lift-off layer P-LOL1 may be located on the first preliminary display panel P-DP to entirely cover the pads PD.

In FIG. 8D, the area of the preliminary first lift-off layer P-LOL1 on a plane is shown in the same as the area of the substrate WP on a plane, but the present disclosure is not limited thereto. For example, the preliminary first lift-off layer P-LOL1 may overlap the display unit area DPA of the substrate WP. For example, the area of the preliminary first lift-off layer P-LOL1 on a plane may be smaller or greater than the area of the substrate WP on a plane.

Referring to FIG. 8C and FIG. 8E together, the preliminary first lift-off layer P-LOL1 may be formed on the substrate on which a first electrode EL1 and an intermediate layer are formed. Particularly, the preliminary first lift-off layer P-LOL1 may be formed on the substrate WP on which a first electrode EL1, hole transport regions HTR1, HTR2, and HTR3, emission layers EML1, EML2, and EML3, and electron transport regions ETR1, ETR2, and ETR3 are formed. The preliminary first lift-off layer P-LOL1 may include a material having low reactivity with the intermediate layer. For example, the preliminary first lift-off layer P-LOL1 may include a material having low chemical reactivity with a material composing the intermediate layer.

In one or more embodiments, the preliminary first lift-off layer P-LOL1 may include a polymer material. For example, the preliminary first lift-off layer P-LOL1 may include a polymer material including fluorine. For example, the preliminary first lift-off layer P-LOL1 may include at least one of polytetrafluoroethylene, polychlorotrifluoroethylene, polydichlorodifluoroethylene, a copolymer of chlorotrifluoroethylene and dichlorodifluoroethylene, a copolymer of tetrafluoroethylene and perfluoroalkyl vinyl ether, a copolymer of chlorotrifluoroethylene and perfluoroalkyl vinyl ether, a copolymer of tetrafluoroethylene and perfluoroalkyl vinyl ether, and/or a copolymer of chlorotrifluoroethylene and perfluoroalkyl vinyl ether. In one or more embodiments, the preliminary first lift-off layer P-LOL1 may include polytetrafluoroethylene.

The preliminary first lift-off layer P-LOL1 may be formed using various suitable methods, such as a coating method, a printing method, or a deposition method. In addition, a curing and polymerization treatment may be carried out as desired during forming the preliminary first lift-off layer P-LOL1.

Referring to FIG. 8F and FIG. 8G, the method for manufacturing a display device according to one or more embodiments of the present disclosure may include a step of forming a first photoresist pattern PR1 on the preliminary first lift-off layer P-LOL1.

The first photoresist pattern PR1 may be formed on the preliminary first lift-off layer P-LOL1 by forming a preliminary first photoresist layer and then patterning the preliminary first photoresist layer using a photo mask. For example, in the patterning process, a photo mask in which a mask opening part corresponding to a display area DA is formed may be provided on the preliminary first photoresist layer, and light may be provided on the preliminary first photoresist layer through the mask opening part. Then, through a developing process on the preliminary first photoresist layer exposed to the light, a part corresponding to the display area DA among the preliminary first photoresist layer may be removed. Through the patterning process, a photo opening part OP-PR overlapping with the display area DA may be formed in the first photoresist pattern PR1. A positive method for removing a part provided with the light among the preliminary first photoresist layer by the patterning method of the preliminary first photoresist layer has been explained, but the present disclosure is not limited thereto. For example, the preliminary first photoresist layer may be patterned by a negative method for removing a part not provided with the light among the preliminary first photoresist layer.

The first photoresist pattern PR1 may overlap with the pad area PA on a plane. The first photoresist pattern PR1 may be formed to overlap with the pads PD on a plane. In addition, as shown in FIG. 8G, the first photoresist pattern PR1 may overlap with the first non-display area NDA1. In one or more embodiments, the first photoresist pattern PR1 may not overlap with the display area DA on a plane.

Referring to FIG. 8H and FIG. 8I, the method for manufacturing a display device according to one or more embodiments of the present disclosure may include a step of etching the preliminary first lift-off layer P-LOL1 (see FIG. 8G) to form a first lift-off layer LOL1.

The first lift-off layer LOL1 may be formed by etching the preliminary first lift-off layer P-LOL1 (see FIG. 8G) using the first photoresist pattern PR1 as a mask. The step of etching the preliminary first lift-off layer P-LOL1 (see FIG. 8G) may include a step of providing a first solvent to the preliminary first lift-off layer P-LOL1 (see FIG. 8G). A part overlapping with the photo opening part OP-PR may be removed from the preliminary first lift-off layer P-LOL1 (see FIG. 8G). In the step of etching the preliminary first lift-off layer P-LOL1 (see FIG. 8G), the first lift-off layer LOL1, in which a lift-off opening part OP-LOL for exposing at least a portion of the display area DA is defined, may be formed. On a plane, the lift-off opening part OP-LOL defined at the first lift-off layer LOL1 may entirely overlap with the display area DA.

In one or more embodiments, the first solvent may include fluorine. By using the first solvent including fluorine as an etching solution, the etching of the preliminary first lift-off layer P-LOL1 including a polymer including fluorine may be smooth. The first solvent may use any one as long as it may dissolve the preliminary first lift-off layer P-LOL1, without limitation, and may include hydrofluoroether (HFE), hydrofluorocarbon, perfluorocarbon, trifluorotoluene, octafluorotoluene, perfluorobenzene, and/or the like. In one or more embodiments, the first solvent may include hydrofluoroether (HFE). The hydrofluoroether (HFE) has little interaction with other materials and is an electrochemically stable material. Accordingly, if the hydrofluoroether (HFE) is used as the first solvent in the step of etching the preliminary first lift-off layer P-LOL1 (see FIG. 8G), damage to the functional layers of the first preliminary display panel P-DP located under the preliminary first lift-off layer P-LOL1 (see FIG. 8G) may be prevented or reduced.

In FIG. 8H and FIG. 8I, the area on a plane of the lift-off opening part OP-LOL defined in the first lift-off layer LOL1 is shown as roughly equal to the area on a plane of the photo opening part OP-PR defined in the first photoresist pattern PR1, but the present disclosure is not limited thereto. The area on a plane of the lift-off opening part OP-LOL defined at the first lift-off layer LOL1 may be larger than the area on a plane of the photo opening part OP-PR defined in the first photoresist pattern PR1. The first lift-off layer LOL1 may have a dented undercut shape from the inner side surface of the first photoresist pattern PR1 defining the photo opening part OP-PR.

The first lift-off layer LOL1 may expose the display area DA. The first lift-off layer LOL1 may overlap with the pad area PA. The first lift-off layer LOL1 may entirely cover the pads PD located in the pad area PA. The first lift-off layer LOL1 may play the role of preventing or reducing the provision of a material forming a second electrode EL2 (see, e.g. FIG. 8J) to the elements located in the pad area PA in the forming step of the second electrode EL2 (see, e.g. FIG. 8J), which will be explained later. Because the first lift-off layer LOL1 covers the pads PD, the deposition of the material forming the second electrode EL2 (see, e.g. FIG. 8J) in the forming step of the second electrode EL2 (see, e.g. FIG. 8J) may be effectively prevented or reduced, and the chances of a short occurring due to the electrode material deposited in the pad area may be prevented or reduced.

Referring to FIG. 8J to FIG. 8L, the method for manufacturing a display device according to one or more embodiments of the present disclosure may include a step of forming a second electrode EL2.

The second electrode EL2 may be formed on an intermediate layer through the photo opening part OP-PR (see FIG. 8H) of the first photoresist pattern PR1. The second electrode EL2 may be formed on preliminary light-emitting elements ED-1I, ED-2I, and ED-3I using the first lift-off layer LOL1 and the first photoresist pattern PR1 as masks. As shown in FIG. 8L, the second electrode EL2 may be formed on the electron transport regions ETR1, ETR2, and ETR3 in the preliminary light-emitting elements ED-11, ED-21, and ED-31.

Referring to FIG. 8K and FIG. 8L, in the step of forming the second electrode EL2, the second electrode EL2 may be formed on the preliminary display element layer PL, and a portion thereof may be formed on the first photoresist pattern.

The step of forming the second electrode EL2 may be performed by a deposition process of a conductive material. The conductive material for forming the second electrode EL2 may include a metal material. For example, the conductive material forming the second electrode EL2 may include a transparent metal oxide. For example, the conductive material forming the second electrode EL2 may include at least one of indium tin oxide (ITO), indium zinc oxide (IZO), zinc oxide (ZnO), or indium tin zinc oxide (ITZO). The conductive material forming the second electrode EL2 may include a metal material, for example, Ag, Mg, Cu, Al, Pt, Pd, Au, Ni, Nd, Ir, Cr, Li, Ca, LiF/Ca, LiF/AI, Mo, Ti, Yb, W, or compounds or mixtures including thereof (for example, AgMg, AgYb or MgAg).

Referring to FIG. 8K, the material forming the second electrode EL2 may be formed on the first photoresist pattern PR1 as well as on the display area DA. The second electrode EL2 may be formed to overlap with the display area DA and the pad area PA. Because the first lift-off layer LOL1 is positioned to overlap with the pad area PA, deposition of the material forming the second electrode EL2 on the pads PD may be prevented or reduced. The second electrode EL2 may make contact with the intermediate layer. For example, as shown in FIG. 8L, the second electrode EL2 may contact the electron transport regions ETR1, ETR2, and ETR3. Through the step of forming the second electrode EL2, light-emitting elements ED1, ED2, and ED3 may be formed. The same contents explained in FIG. 6A may be applied for the light-emitting elements ED1, ED2, and ED3.

Referring to FIG. 8M to FIG. 80, the method for manufacturing a display device according to one or more embodiments of the present disclosure may further include a step of forming an optical layer OPL on the second electrode EL2.

After the step of forming the second electrode EL2, the optical layer OPL may be formed through the photo opening part OP-PR (see, e.g. FIG. 8H) of the first photoresist pattern PR1. In one or more embodiments, the step of forming the optical layer OPL may be performed through a deposition process. Referring to FIG. 8N and FIG. 8O, the optical layer OPL may be formed on the second electrode EL2. The optical layer OPL may make contact with the second electrode EL2. Referring to FIG. 8N, a material forming the optical layer OPL may be provided on the first photoresist pattern PR1.

Referring to FIG. 8P and FIG. 8Q, the method for manufacturing a display device according to one or more embodiments of the present disclosure may include a step of removing the first lift-off layer LOL1 (see FIG. 8M) and the first photoresist pattern PR1 (see FIG. 8M).

The step of removing the first lift-off layer LOL1 (see FIG. 8M) and the first photoresist pattern PR1 (see FIG. 8M) may include a step of treating the first lift-off layer LOL1 (see FIG. 8M) and the first photoresist pattern PR1 (see FIG. 8M) with a second solvent.

In one or more embodiments, the second solvent may include fluorine. If the first lift-off layer LOL1 (see FIG. 8M) includes a fluoropolymer, the first lift-off layer LOL1 (see FIG. 8M) may be removed from the substrate WP (see FIG. 8M) by using a solvent including fluorine. The second solvent may dissolve the first lift-off layer LOL1 (see FIG. 8M), and may include, for example, hydrofluoroether (HFE), hydrofluorocarbon, perfluorocarbon, trifluorotoluene, octafluorotoluene, perfluorobenzene or the like. In one or more embodiments, the second solvent may include hydrofluoroether (HFE). The hydrofluoroether (HFE) has little interaction with other materials and is an electrochemically stable material. Accordingly, if the hydrofluoroether (HFE) is used as the second solvent, in the step of removing the first lift-off layer LOL1 (see FIG. 8M) and the first photoresist pattern PR1 (see FIG. 8M), damage to the functional layers included at the display element layer DP-LED may be prevented or reduced.

Referring to FIG. 8N and FIG. 8Q together, in the step of removing the first lift-off layer LOL1 and the first photoresist pattern PR1, the second electrode EL2 and the optical layer OPL, formed on the first photoresist pattern PR1, may be removed, and the second electrode EL2 and the optical layer OPL, formed on the preliminary display element layer PL, may remain. The first lift-off layer LOL1 may protect the pads PD disposed in the pad area PA during forming the second electrode EL2 and the optical layer OPL. The first lift-off layer LOL1 may prevent or reduce the generation of defects, such as short phenomenon, due to the deposition of the material forming the second electrode EL2 on the pads PD located in the pad area PA during forming the second electrode EL2. Through the step of removing the first lift-off layer LOL1 and the first photoresist pattern PR1, the display element layer DP-LED may be formed on the circuit element layer DP-CL.

The method for manufacturing a display device according to one or more embodiments of the present disclosure may further include after the step of removing the first lift-off layer LOL1 and the first photoresist pattern PR1 and a step of providing an encapsulation substrate ES (see FIG. 2B). A sealant SM (see FIG. 2B) may be formed on one surface of the encapsulation substrate ES (see FIG. 2B), and a base substrate BS (see FIG. 2B) and the encapsulation substrate ES (see FIG. 2B) may be attached. Through the step of providing the encapsulation substrate ES (see FIG. 2B), the display device DD, including the display panel DP according to one or more embodiments, explained referring to FIG. 2B, may be formed.

According to the present disclosure, the steps of forming the second electrode EL2 and the optical layer OPL may be performed by a lift-off process, and mis-alignment issues of a substrate and a metal mask may be prevented or reduced.

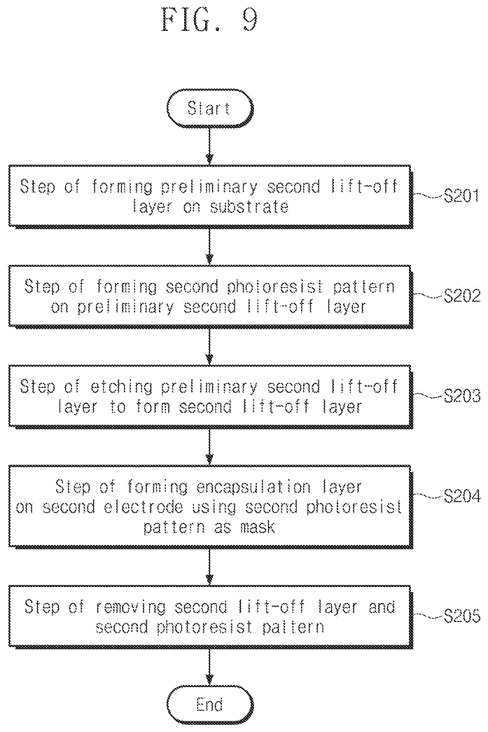

FIG. 9 illustrates a flowchart showing some steps in the method for manufacturing a display device according to one or more embodiments. FIG. 9 illustrates a flowchart showing a step of forming an encapsulation layer TFE in the display device according to one or more embodiments of the present disclosure. Referring to FIG. 9, the method for manufacturing a display device according to one or more embodiments of the present disclosure may include a step of forming a preliminary second lift-off layer on a substrate (S201), a step of forming a second photoresist pattern on the preliminary second lift-off layer (S202), a step of etching the preliminary second lift-off layer to form a second lift-off layer (S203), a step of forming an encapsulation layer on a second electrode using the second photoresist pattern as a mask (S204), and a step of removing the second lift-off layer and the second photoresist pattern (S205).

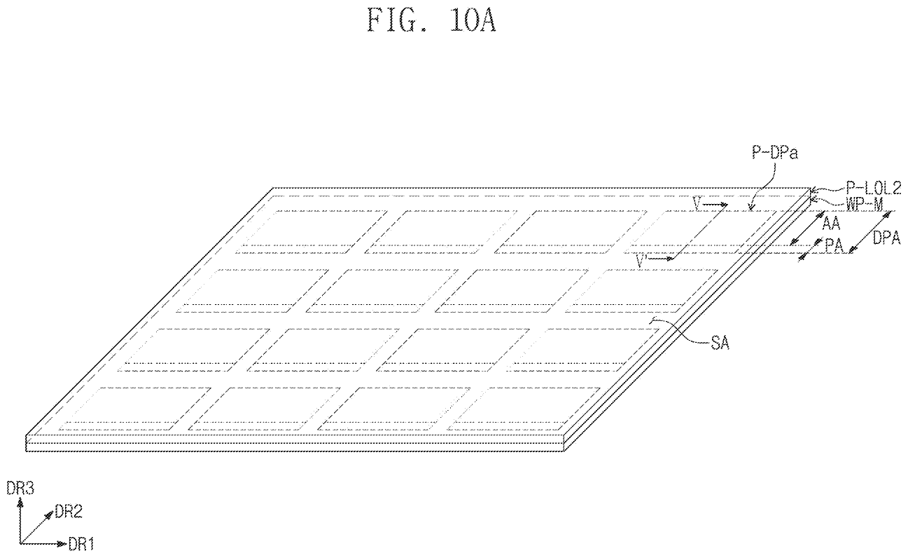

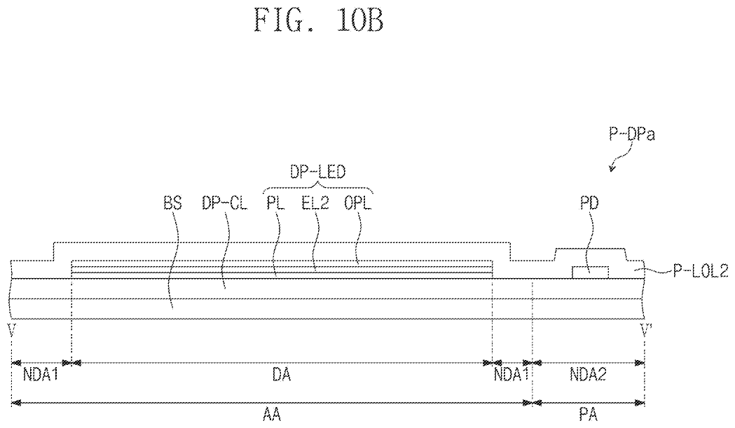

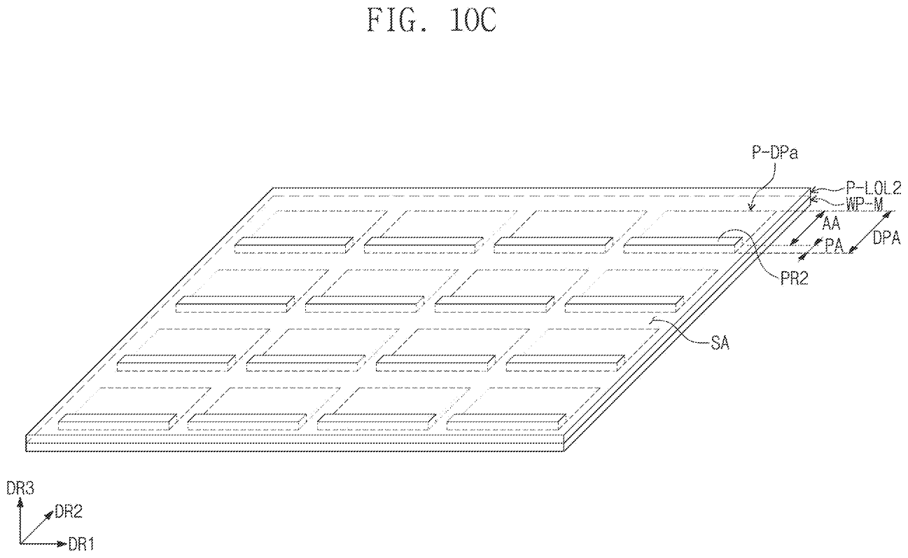

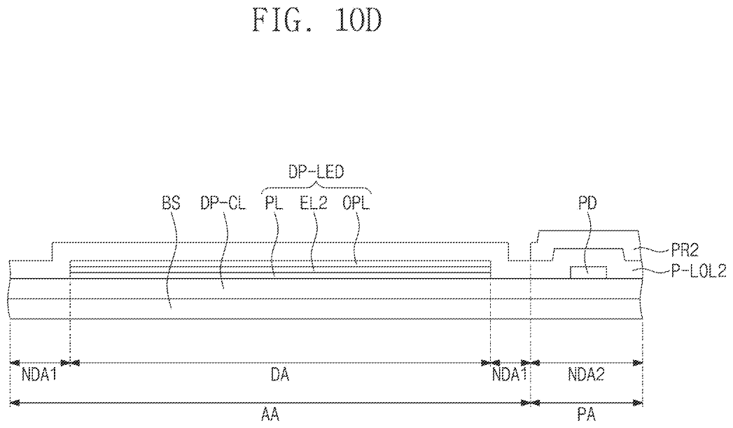

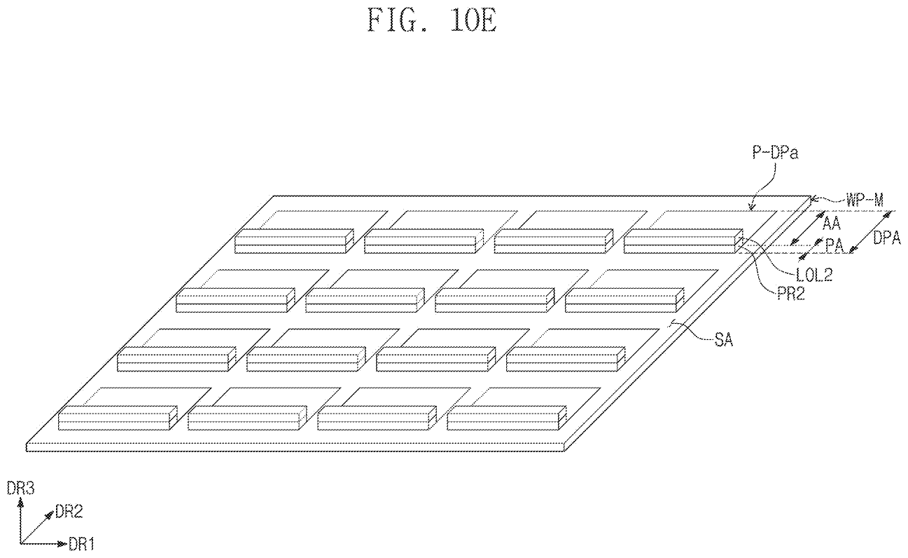

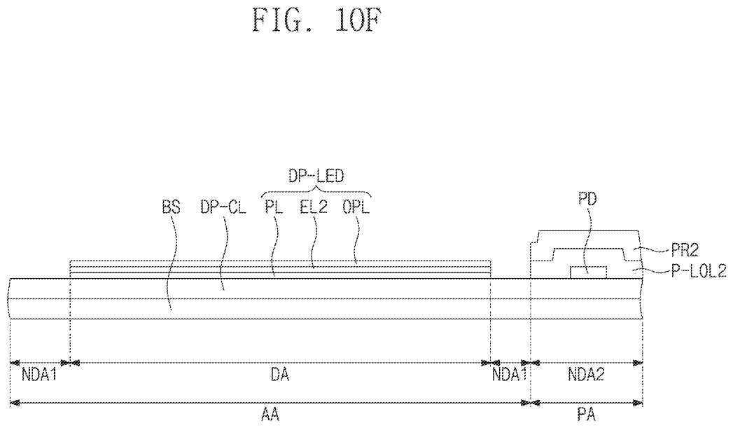

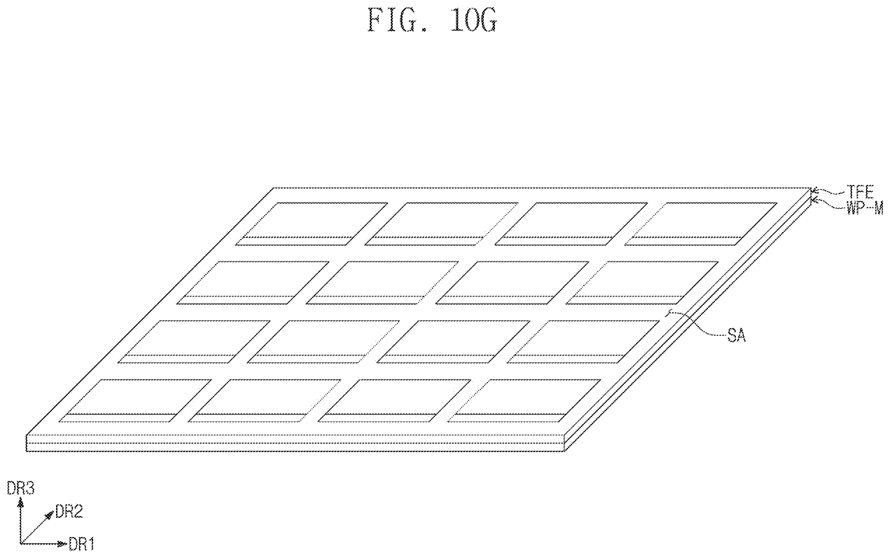

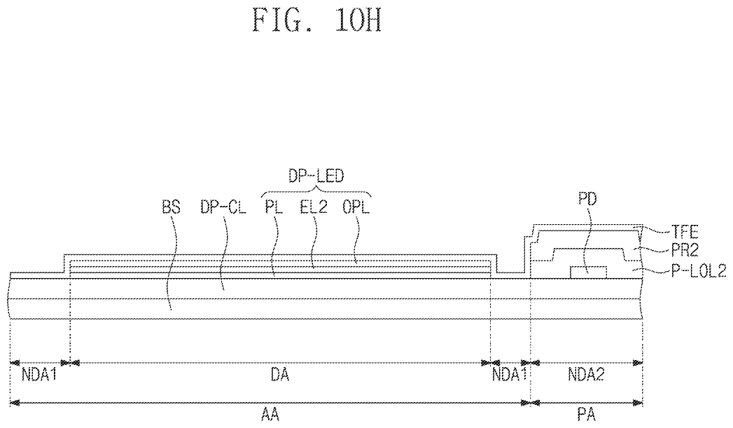

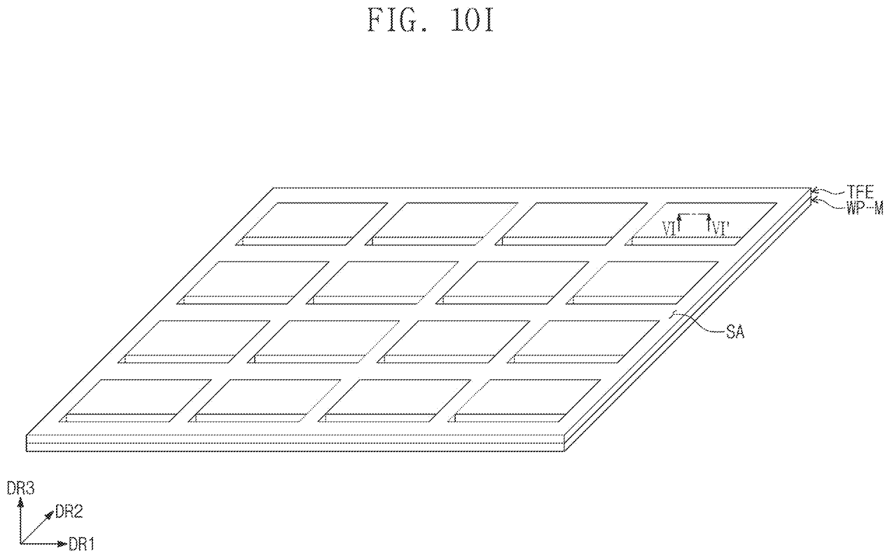

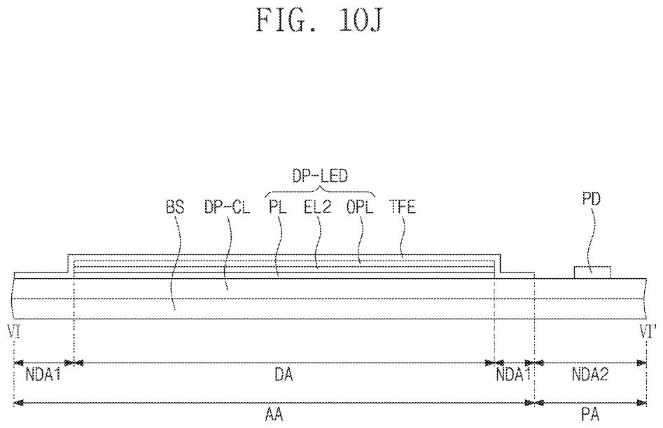

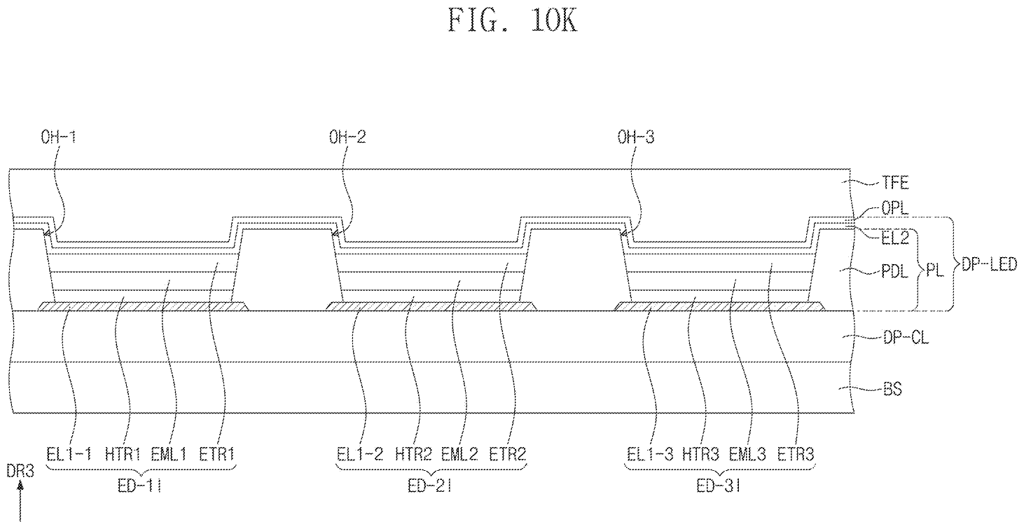

FIGS. 10A to FIG. 10K illustrate cross-sectional views showing some steps of the method for manufacturing a display device according to one or more embodiments of the present disclosure. FIG. 10A, FIG. 10C, FIG. 10E, FIG. 10G and FIG. 10I illustrate perspective views of the method for manufacturing a display device according to one or more embodiments of the present disclosure. FIG. 10B, FIG. 10D, FIG. 10F, FIG. 10H, FIG. 10J and FIG. 10K illustrate cross-sectional views of the method for manufacturing a display device according to one or more embodiments of the present disclosure. FIG. 10B, FIG. 10D, FIG. 10F, FIG. 10H, and FIG. 10J illustrate cross-sectional views showing the method for manufacturing a display device in order, on cross-sections taken along the line V-V′ in FIGS. 10A. FIG. 10K illustrate a cross-sectional view showing some steps of the method for manufacturing a display device, on a cross-section taken along the line VI-VI′ in FIG. 10I.

A display device manufactured by the method for manufacturing a display device according to one or more embodiments, explained referring to FIG. 10A to FIG. 10K may have the structure of the display device according to one or more embodiments, explained referring to FIG. 1 to FIG. 2A, and FIG. 3 to FIG. 6B. Accordingly, in the explanation on the method for manufacturing a display device according to one or more embodiments, referring to FIG. 10A to FIG. 10K, the same reference symbols are given for the same elements of the display device of FIG. 1 to FIG. 2A, and FIG. 3 to FIG. 6B, and description overlapping therewith will be omitted.

Referring to FIG. 10A and FIG. 10B, the method for manufacturing a display device according to one or more embodiments of the present disclosure may include a step of forming a preliminary second lift-off layer P-LOL2 on the substrate WP-M. In addition, the method for manufacturing a display device according to one or more embodiments of the present disclosure may further include a step of providing a substrate WP-M.

Referring to FIG. 10A, the substrate WP-M may be a large-sized mother glass substrate. For example, multiple second preliminary display panels P-Dpa may be formed at the substrate WP-M. The second preliminary display panels P-Dpa may be separately arranged on a plane.

Referring to FIG. 8P, FIG. 8Q, FIG. 10A and FIG. 10B together, the substrate WP-M may be a substrate on which a second electrode EL2 is formed on a substrate WP, as explained through FIG. 8A to FIG. 8Q. The substrate WP-M may be a substrate in which a second electrode EL2 and an optical layer OPL are formed on a substrate WP, as explained through FIG. 8A to FIG. 8Q. The same contents explained in FIG. 8A or the like may be applied for an active area AA, a pad area PA, and a peripheral area SA, included at the substrate WP-M.

The second preliminary display panel P-Dpa may be defined as the elements included in the display panel DP explained in FIG. 6A and FIG. 6B and the elements prior to the step of forming an encapsulation layer TFE (see FIG. 10G). The second preliminary display panel P-Dpa may include the same elements as the elements of the above-described display panel DP (see FIG. 6A) except for the encapsulation layer TFE (see FIG. 10G). The second preliminary display panel P-Dpa may include a base substrate BS, a circuit element layer DP-CL, first electrodes EL1-1, EL1-2, and EL1-3, an intermediate layer, and a second electrode EL2. In addition, the second preliminary display panel P-Dpa may further include an optical layer OPL located on the second electrode EL2. The same contents explained on the first preliminary display panel P-DP may be applied for the intermediate layer.

Referring to FIG. 10A and FIG. 10B again, the preliminary second lift-off layer P-LOL2 may be formed on the substrate WP-M. The preliminary second lift-off layer P-LOL2 may entirely overlap with the second preliminary display panel P-Dpa. The preliminary second lift-off layer P-LOL2 may be provided to overlap with the active area DA, the pad area PA, and the peripheral area SA of the substrate WP-M.

While, in FIG. 10A, the area on a plane of the preliminary second lift-off layer P-LOL2 is shown as being roughly equal to the area on a plane of the substrate WP-M, the present disclosure is not limited thereto. For example, it is sufficient that only the preliminary second lift-off layer P-LOL2 overlaps with the display unit area DPA of the substrate WP-M. For example, the area on a plane of the preliminary second lift-off layer P-LOL2 may be smaller or greater than the area on a plane of the substrate WP-M.

Referring to FIG. 8P, FIG. 8Q, FIG. 10A and FIG. 10B together, the preliminary second lift-off layer P-LOL2 may be formed on the substrate WP-M in which the second electrode EL2 and the optical layer OPL are formed. The preliminary second lift-off layer P-LOL2 may be formed on the substrate WP-M on which a first electrode EL1 (see FIG. 6A), hole transport regions HTR1, HTR2, and HTR3 (see FIG. 6A), emission layers EML1, EML2, and EML3 (see FIG. 6A), electron transport regions ETR1, ETR2, and ETR3 (see FIG. 6A), a second electrode EL2 (see FIG. 6A) and an optical layer OPL (see FIG. 6A) are formed. The preliminary second lift-off layer P-LOL2 may include a material having low reactivity with the functional layers included in the second preliminary display panel P-Dpa.

In one or more embodiments, the preliminary second lift-off layer P-LOL2 may include a polymer material. For example, the preliminary second lift-off layer P-LOL2 may include a polymer material including fluorine. For example, the preliminary second lift-off layer P-LOL2 may include at least one of polytetrafluoroethylene, polychlorotrifluoroethylene, polydichlorodifluoroethylene, a copolymer of chlorotrifluoroethylene and dichlorodifluoroethylene, a copolymer of tetrafluoroethylene and perfluoroalkyl vinyl ether, a copolymer of chlorotrifluoroethylene and perfluoroalkyl vinyl ether, a copolymer of tetrafluoroethylene and perfluoroalkyl vinyl ether, or a copolymer of chlorotrifluoroethylene and perfluoroalkyl vinyl ether. In one or more embodiments, the preliminary second lift-off layer P-LOL2 may include polytetrafluoroethylene.

The preliminary second lift-off layer P-LOL2 may be formed using various suitable methods, such as a coating method, a printing method and a deposition method. In addition, a curing and polymerization treatment may be carried out as desired during forming the preliminary second lift-off layer P-LOL2.

Referring to FIG. 10C and FIG. 10D, the method for manufacturing a display device according to one or more embodiments of the present disclosure may include a step of forming a second photoresist pattern PR2 on the preliminary second lift-off layer P-LOL2.

The second photoresist pattern PR2 may be formed on the preliminary second lift-off layer P-LOL2 by forming a preliminary second photoresist layer and then patterning the preliminary second photoresist layer using a photo mask. For example, in the patterning process, a second photoresist pattern PR2 may be formed by exposing a part other than a part overlapping with the pad area PA among the preliminary second photoresist layer and removing the exposed part by development. A positive method for removing a part provided with the light among the preliminary second photoresist layer by the patterning method of the preliminary second photoresist layer has been explained, but the present disclosure is not limited thereto. For example, the preliminary second photoresist layer may be patterned by a negative method for removing a part not provided with the light among the preliminary second photoresist layer.

The second photoresist pattern PR2 may overlap with the pad area PA on a plane. The second photoresist pattern PR2 may be formed to overlap with the pads PD on a plane. The second photoresist pattern PR2 may not overlap with the display area DA on a plane. In addition, the second photoresist pattern PR2 may not overlap with the first non-display area NDA1. However, the present disclosure is not limited thereto. The second photoresist pattern PR2 may partially overlap with the first non-display area NDA1 on a plane.

Referring to FIG. 10E and FIG. 10F, the method for manufacturing a display device according to one or more embodiments of the present disclosure may include a step of etching the preliminary second lift-off layer P-LOL2 (see FIG. 10D) to form a second lift-off layer LOL2.

A second lift-off layer LOL2 may be formed by etching the preliminary second lift-off layer P-LOL2 using the second photoresist pattern PR2 as a mask. The step of etching the preliminary second lift-off layer P-LOL2 may include a step of providing a third solvent to the preliminary second lift-off layer P-LOL2 (see FIG. 10D). A part overlapping with the display area DA at the preliminary second lift-off layer P-LOL2 (see FIG. 10D) may be removed. In addition, as shown in FIG. 10F, a part overlapping with the first non-display area NDA1 at the preliminary second lift-off layer P-LOL2 (see FIG. 10D) may be removed.

In the step of etching the preliminary second lift-off layer P-LOL2 (see FIG. 10D), the second lift-off layer LOL2 exposing the display area DA may be formed. In the step of etching the preliminary second lift-off layer P-LOL2 (see FIG. 10D), the preliminary second lift-off layer P-LOL2 (see FIG. 10D) overlapping with the display area DA may be entirely etched to form the second lift-off layer LOL2.

In one or more embodiments, the third solvent may include fluorine. By using the third solvent including fluorine as an etching solution, the etching of the preliminary second lift-off layer P-LOL2 (see FIG. 10D) including a polymer including fluorine may be suitably performed. The third solvent may dissolve the preliminary second lift-off layer P-LOL2 (see FIG. 10D) The third solvent may include, for example, hydrofluoroether (HFE), hydrofluorocarbon, perfluorocarbon, trifluorotoluene, octafluorotoluene, perfluorobenzene, or the like. In one or more embodiments, the third solvent may include hydrofluoroether (HFE). The hydrofluoroether (HFE) has little interaction with other materials and is an electrochemically stable material. Accordingly, if the hydrofluoroether (HFE) is used as the third solvent, in the step of etching the preliminary second lift-off layer P-LOL2 (see FIG. 10D), damage to the functional layers located under the preliminary second lift-off layer P-LOL2 (see FIG. 10D) may be prevented or reduced.

The second lift-off layer LOL2 may overlap with the pad area PA. The second lift-off layer LOL2 may entirely cover the pads PD located in the pad area PA. The second lift-off layer LOL2 may not overlap with the display area DA. The second lift-off layer LOL2 may not overlap with the first non-display area NDA1. The second lift-off layer LOL2 may play the role of preventing or reducing the provision of the elements located in the pad area PA with a material forming the encapsulation layer TFE (see FIG. 10H) in the step of forming the encapsulation layer TFE (see FIG. 10H), which will be explained later.

In FIG. 10E and FIG. 10F, the second lift-off layer LOL2 and the second photoresist pattern PR2 are shown to not overlap with the peripheral area SA, but the present disclosure is not limited thereto. The second lift-off layer LOL2 may overlap with the pad area PA and the peripheral area SA of the substrate WP-M. In this case, a lift-off opening part overlapping with the display area DA may be defined at the second lift-off layer LOL2. The planar layout of the second lift-off layer LOL2 may be modified by changing the shape of the second photoresist pattern PR2.

Referring to FIG. 10G and FIG. 10H, the method for manufacturing a display device according to one or more embodiments of the present disclosure may include a step of forming an encapsulation layer TFE on the second electrode EL2 using the second photoresist pattern PR2 as a mask.

Referring to FIG. 10E to FIG. 10H together, an encapsulation layer TFE may be formed on the display element layer DP-LED using the second lift-off layer LOL2 and the second photoresist pattern PR2 as masks. The encapsulation layer TFE may be formed on the second electrode EL2. If the display element layer DP-LED includes an optical layer OPL, the encapsulation layer TFE may be formed on the optical layer OPL. In the step of forming the encapsulation layer TFE, the encapsulation layer TFE may be formed on the display element layer DP-LED and may partially be formed on the second photoresist pattern PR2.

A material forming the encapsulation layer TFE may be provided in the display area DA. The material forming the encapsulation layer TFE may be provided in the display area DA and the first non-display area NDA1 surrounding the display area DA. Accordingly, the encapsulation layer TFE may be formed to completely cover the display element layer DP-LED. Because the second lift-off layer LOL2 is positioned to overlap with the pad area PA, the deposition of the material forming the encapsulation layer TFE on the pads PD may be prevented or reduced.

The encapsulation layer TFE may be formed to have a single layer structure or a multilayer structure. For example, a step of forming a first inorganic layer IOL1 (see FIG. 5) on the second electrode, a step of forming an organic layer OL (see FIG. 5) on the first inorganic layer IOL1 (see FIG. 5), and a step of forming a second inorganic layer IOL2 (see FIG. 5) on the organic layer OL (see FIG. 5) may be performed. The first inorganic layer IOL1 (see FIG. 5), the organic layer OL (see FIG. 5) and the second inorganic layer IOL2 (see FIG. 5) may be formed in order on the second electrode EL2 using the second lift-off layer LOL2 and the second photoresist pattern PR2 as masks.

Referring to FIG. 10I to FIG. 10K, the method for manufacturing a display device according to one or more embodiments of the present disclosure may include a step of removing the second lift-off layer LOL2 (see FIG. 10E) and the second photoresist pattern PR2 (see FIG. 10E).

The step of removing the second lift-off layer LOL2 (see FIG. 10E) and the second photoresist pattern PR2 (see FIG. 10E) may include a step of treating the second lift-off layer LOL2 (see FIG. 10E) and the second photoresist pattern PR2 (see FIG. 10E) with a fourth solvent.

In one or more embodiments, the fourth solvent may include fluorine. If the second lift-off layer LOL2 (see FIG. 10E) includes a fluoropolymer, the second lift-off layer LOL2 (see FIG. 10E) may be removed using a solvent including fluorine. The fourth solvent may dissolve the second lift-off layer LOL2 (see FIG. 10E), and may include, for example, hydrofluoroether (HFE), hydrofluorocarbon, perfluorocarbon, trifluorotoluene, octafluorotoluene, perfluorobenzene, or the like. In one or more embodiments, the fourth solvent may include hydrofluoroether (HFE). The hydrofluoroether (HFE) has little interaction with other materials and is an electrochemically stable material. If hydrofluoroether (HFE) is used as the fourth solvent, in the step of removing the second lift-off layer LOL2 and the second photoresist pattern PR2 (see FIG. 10E), damage to the functional layers included at the display element layer DP-LED may be prevented or reduced.

In the step of removing the second lift-off layer LOL2 and the second photoresist pattern PR2 (see FIG. 10E), the encapsulation layer TFE formed on the second photoresist pattern PR2 (see FIG. 10E) may be removed, and the encapsulation layer TFE formed on the display element layer DP-LED may remain. The second lift-off layer LOL2 (see FIG. 10E) may protect the pads PD located in the pad area PA during forming the encapsulation layer TFE. Through the step of removing the second lift-off layer LOL2 (see FIG. 10E) and the second photoresist pattern PR2, the encapsulation layer TFE may be formed on the display element layer DP-LED.

After the step of removing the second lift-off layer LOL2 (see FIG. 10E) and the second photoresist pattern PR2 (see FIG. 10E), a step of cutting the substrate WP-M to separate multiple display panels DP (see FIG. 6A) may be performed. As shown in FIG. 10K, each of the separated multiple display panels DP (see FIG. 6A) may include a base substrate BS, a circuit element layer DP-CL, and a display element layer DP-LED.

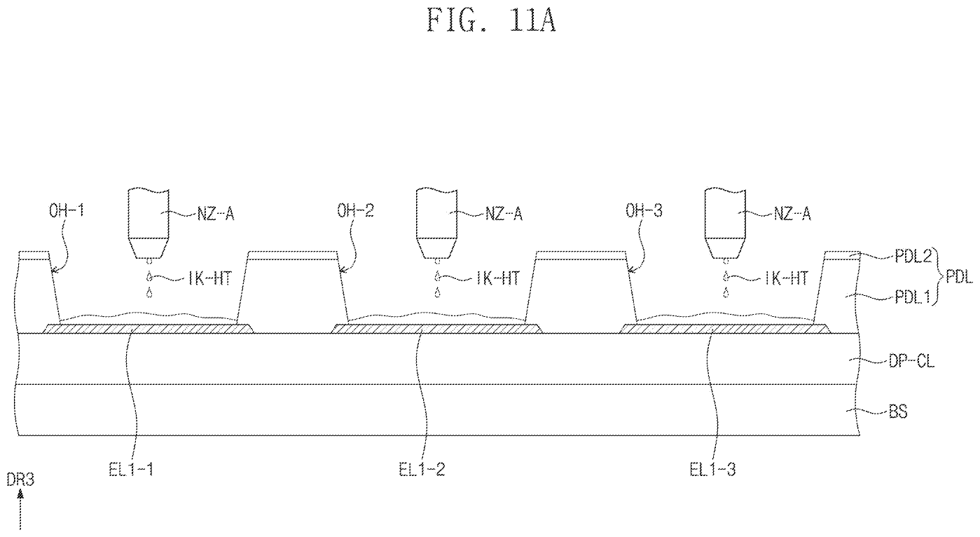

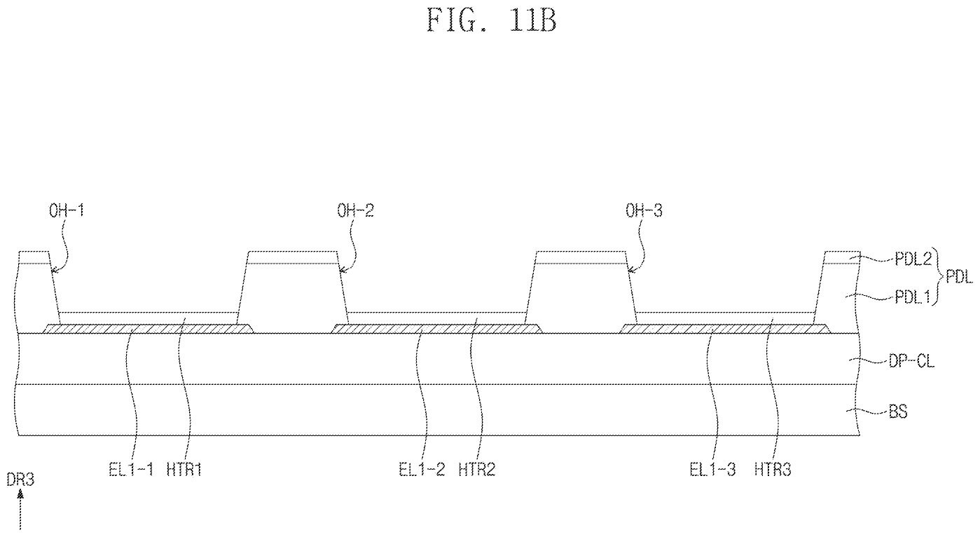

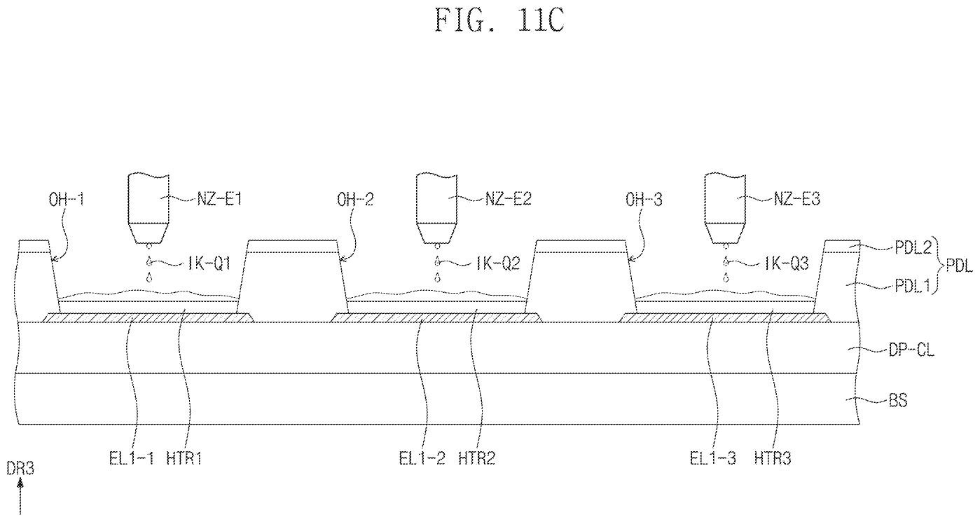

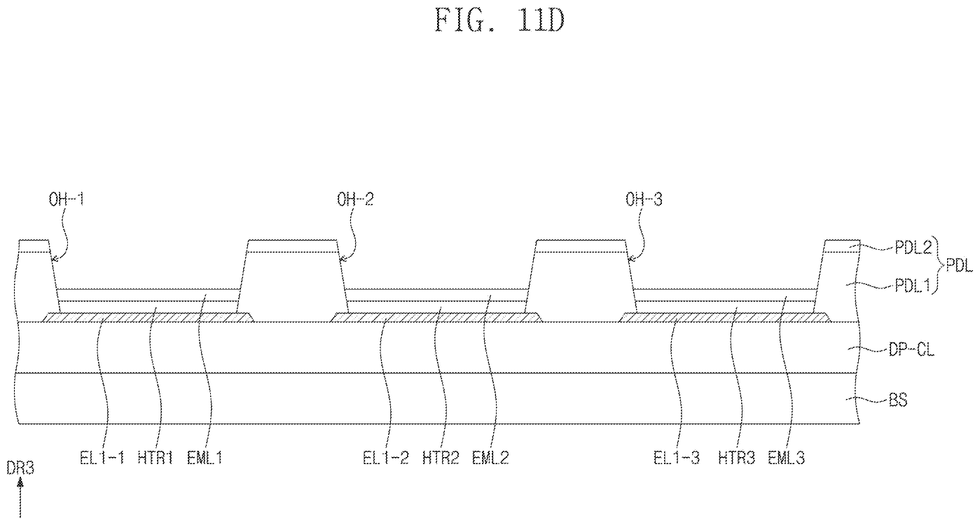

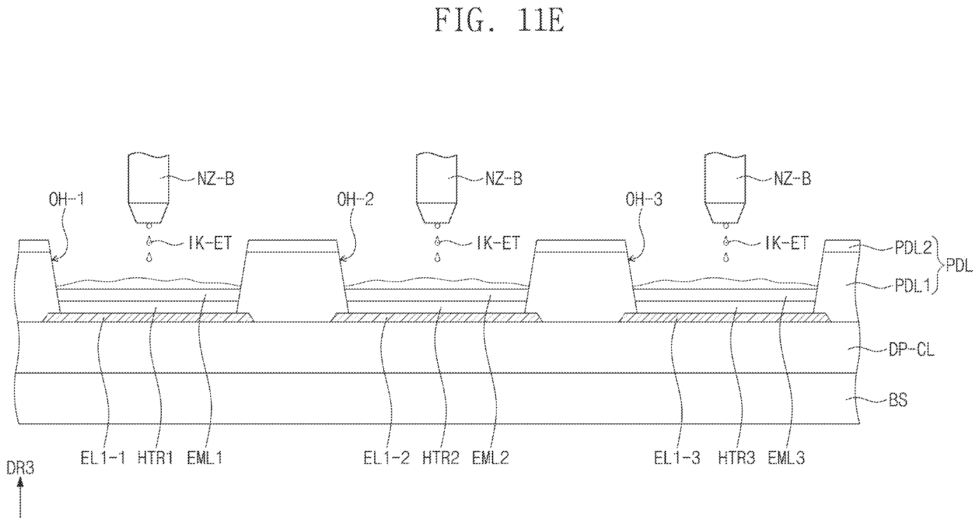

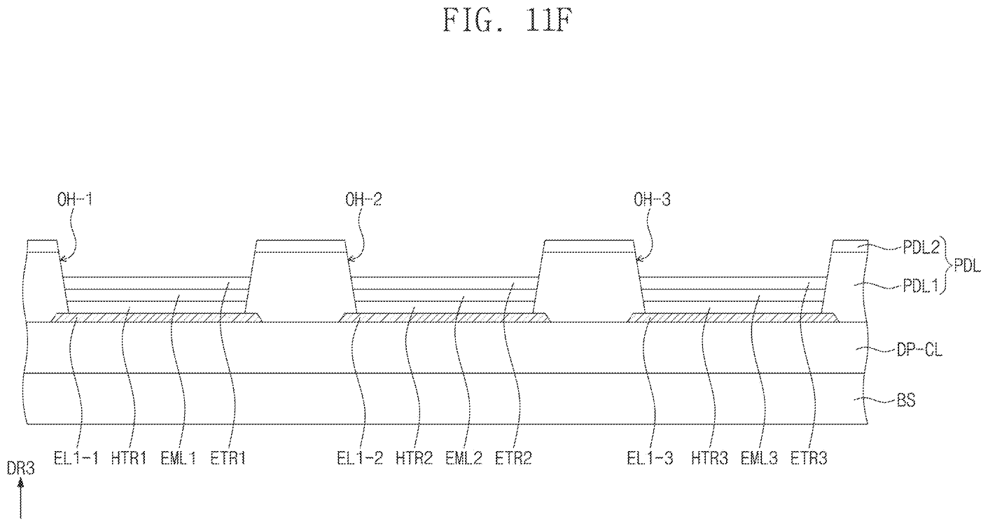

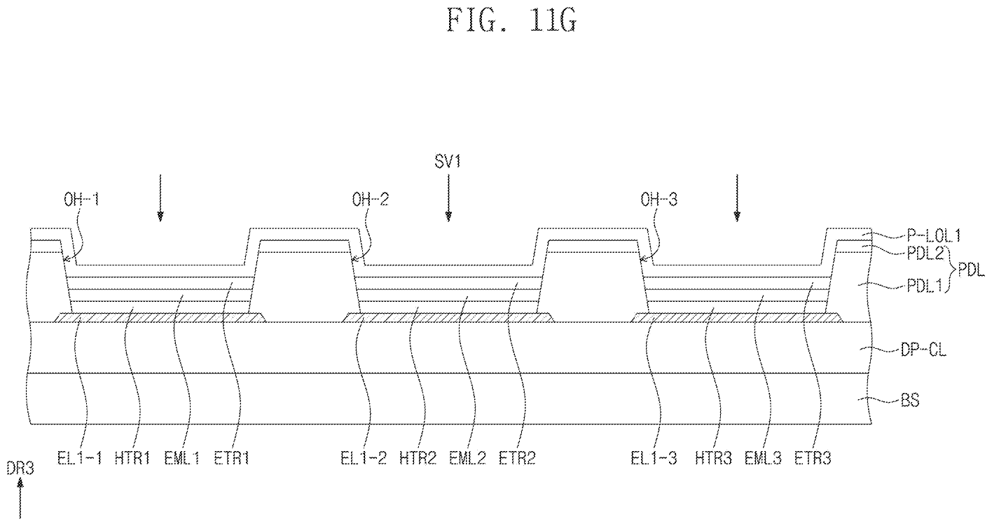

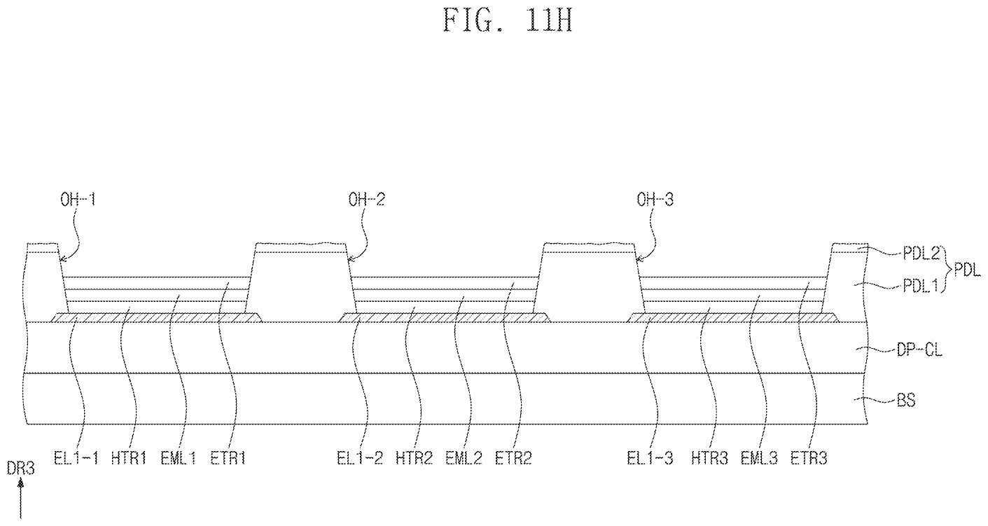

FIG. 11A to FIG. 11H show the steps of the method for manufacturing a display device according to one or more embodiments of the present disclosure. Hereinafter, in the explanation on the method for manufacturing a display device according to one or more embodiments of the present disclosure, referring to FIG. 11A to FIG. 11H, the same reference symbols are designated for the same elements as those of the display device in FIG. 1 to FIG. 6B, and overlapping explanation thereon will be omitted.

Referring to FIG. 11A, in the method for manufacturing a display device according to one or more embodiments, a circuit element layer DP-CL may be formed on a base substrate BS, and a pixel definition layer PDL may be formed on the circuit element layer DP-CL. For example, multiple pixel opening parts OH-1, OH-2, and OH-3 may be defined at the pixel definition layer PDL.

Prior to forming the pixel definition layer PDL, first electrodes EL1-1, EL1-2, and EL1-3 may be formed on the circuit element layer DP-CL. The first electrodes EL1-1, EL1-2, and EL1-3 may be patterned on the circuit element layer DP-CL. The first electrodes EL1-1, EL1-2, and EL1-3 may be separated from each other on a plane and may include a first sub electrode EL1-1, a second sub electrode EL1-2, and a third sub electrode EL1-3. The tops of the first sub electrode EL1-1, the second sub electrode EL1-2, and the third sub electrode EL1-3 may be exposed through the pixel opening parts OH-1, OH-2, and OH-3, respectively. The edge parts of the first electrodes EL1-1, EL1-2, and EL1-3 may be partially overlapped with the pixel definition layer PDL.

The pixel opening parts OH-1, OH-2, and OH-3 may be parts corresponding to the first to third light-emitting areas PXA-R, PXA-G, and PXA-B, explained in FIG. 3.

The pixel definition layer PDL may include a first pixel definition part PDL1 and a second pixel definition part PDL2. The first pixel definition part PDL1 may be located on the circuit element layer DP-CL, and the second pixel definition part PDL2 may be located on the first pixel definition part PDL1. The second pixel definition part PDL2 may be located directly on the first pixel definition part PDL1. The second pixel definition part PDL2 may cover the top of the first pixel definition part PDL1. The second pixel definition part PDL2 may be referred to as a liquid-repelling part.

The first pixel definition part PDL1 may include an inorganic material. For example, the first pixel definition part PDL1 may include at least one of silicon nitride (SiNₓ), silicon oxide (SiOₓ), or silicon oxynitride (SiOₓN_{y}). The first pixel definition part PDL1 may include silicon nitride (SiNₓ).

The second pixel definition part PDL2 may include a liquid-repelling additive. The second pixel definition part PDL2 may be formed by including the liquid-repelling additive. For example, the second pixel definition part PDL2 may be formed by including a polymer resin and a liquid-repelling additive. In one or more embodiments, the liquid-repelling additive may include fluorine. For example, the liquid-repelling additive may include a fluorine compound. The second pixel definition part PDL2 may be formed by including a liquid-repelling additive including a fluorine compound. Because the pixel definition layer PDL includes a liquid-repelling part including the liquid-repelling additive, ink may make contact with the surface of the liquid-repelling part in an inkjet process, which will be explained later, and thus, the overflow phenomenon of the ink may be prevented or reduced.

FIG. 11A to FIG. 11F show the step of forming an intermediate layer on the first electrodes EL1-1, EL1-2, and EL1-3. In one or more embodiments, the step of forming the intermediate layer may be carried out through an inkjet process.

Referring to FIG. 11A and FIG. 11B, hole transport regions HTR1, HTR2, and HTR3 may be formed on the first electrodes EL1-1, EL1-2, and EL1-3. In one or more embodiments, the step of forming the hole transport regions HTR1, HTR2 and HTR3 may be performed through an inkjet process. Hole transport region ink IK-HT may be applied on the first electrodes EL1-1, EL1-2, and EL1-3 to form the hole transport regions HTR1, HTR2, and HTR3. The hole transport region ink IK-HT may be applied through a first nozzle NZ-A. The hole transport regions HTR1, HTR2, and HTR3 may be formed in the first to third pixel opening parts OH-1, OH-2, and OH-3.

Referring to FIG. 11C and FIG. 11D, emission layers EML1, EML2, and EML3 may be formed on the hole transport regions HTR1, HTR2, and HTR3. In one or more embodiments, the step of forming the hole transport regions HTR1, HTR2 and HTR3 may be performed through an inkjet process. Emission layer ink IK-Q1, IK-Q2, and IK-Q3 may be applied on the hole transport regions HTR1, HTR2, and HTR3 to form the emission layers EML1, EML2, and EML3. The first emission layer ink IK-Q1 may be applied into the first pixel opening part OH-1 to form the first emission layer EML1. The second emission layer ink IK-Q2 may be applied into the second pixel opening part OH-2 to form the second emission layer EML2. The third emission layer ink IK-Q3 may be applied into the third pixel opening part OH-3 to form the third emission layer EML3. The emission layer ink IK-Q1, IK-Q2, and IK-Q3 may be applied through second nozzles NZ-E1, NZ-E2, and NZ-E3, respectively. The second nozzles NZ-E1, NZ-E2, and NZ-E3 may include a first sub nozzle NZ-E1 applying the first emission layer ink IK-Q1, a second sub nozzle NZ-E2 applying the second emission layer ink IK-Q2, and a third sub nozzle NZ-E3 applying the third emission layer ink IK-Q3.

The first emission layer ink IK-Q1, the second emission layer ink IK-Q2, and the third emission layer ink IK-Q3 may be respectively applied into the pixel opening parts OH-1, OH-2, and OH-3 by an inkjet printing method to form the emission layers EML1, EML2, and EML3. The first emission layer ink IK-Q1, the second emission layer ink IK-Q2, and the third emission layer ink IK-Q3 may each independently include an organic light-emitting body or an inorganic light-emitting body.

Referring to FIG. 11E and FIG. 11F, electron transport regions ETR1, ETR2, and ETR3 may be formed on the emission layers EML1, EML2, and EML3. In one or more embodiments, a step of forming the electron transport regions ETR1, ETR2, and ETR3 may be performed through an inkjet process. Electron transport region ink IK-ET may be applied on the emission layers EML1, EML2, and EML3 to form the electron transport regions ETR1, ETR2, and ETR3. The electron transport region ink IK-ET may be applied through a third nozzle NZ-B. The electron transport regions ETR1, ETR2, and ETR3 may be formed in the first to third pixel opening parts OH-1, OH-2, and OH-3.

Through the processes of FIG. 11A to FIG. 11F, an intermediate layer may be formed on the first electrodes EL1-1, EL1-2, and EL1-3. Then, a second electrode EL2, an optical layer OPL and an encapsulation layer TFE may be formed by the same or substantially the same method described in FIG. 8D to FIG. 8Q, and FIG. 10A to FIG. 10K, to form the display panel DP shown in FIG. 10K.

FIG. 11G and FIG. 11H are diagrams showing a step of providing a preliminary first lift-off layer P-LOL1 and a step of etching in the method for manufacturing a display device according to one or more embodiments of the present disclosure as an example. The step of etching the preliminary first lift-off layer P-LOL1, shown in FIG. 11G and FIG. 11H may correspond to the above-described step of etching the preliminary first lift-off layer P-LOL1 in FIG. 8H and FIG. 8I.

Referring to FIG. 11G, in the step of providing the preliminary first lift-off layer P-LOL1, the preliminary first lift-off layer P-LOL1 may be formed on the intermediate layer and the pixel definition layer PDL.

Referring to FIG. 11G and FIG. 11H, in the step of etching the preliminary first lift-off layer P-LOL1, a first solvent SV1 may be applied on the preliminary first lift-off layer P-LOL1. As described above, the first solvent SV1 including fluorine may be used for etching the preliminary first lift-off layer P-LOL1 including a fluoropolymer. Through the treatment using the first solvent SV1, the preliminary first lift-off layer P-LOL1 corresponding to the display area DA may be removed. In this case, a portion of the second pixel definition part PDL2 of the pixel definition layer PDL may be dissolved in the first solvent SV1 and removed. Accordingly, the top of the second pixel definition part PDL2 may have irregular surface roughness.

According to one or more embodiments of the present disclosure, a method for manufacturing a display device in which a manufacturing process is simplified, may be provided.

Although the embodiments of the present disclosure have been described, it is understood that the present disclosure should not be limited to these embodiments, but various suitable changes and modifications can be made by one ordinary skilled in the art within the spirit and scope of the present disclosure, as define by the following claims and equivalents thereof.

1 what is claimed is:

1. A method for manufacturing a display device, the method comprising:
preparing a substrate comprising a display area, a pad area, a peripheral area, a first electrode, and an intermediate layer, the first electrode and the intermediate layer being in the display area;
forming a preliminary first lift-off layer on the substrate;
forming a first photoresist pattern on the preliminary first lift-off layer and defining a photo-opening part overlapping with the display area;
etching the preliminary first lift-off layer to form a first lift-off layer exposing the display area;
forming a second electrode on the intermediate layer through the photo-opening part; and
removing the first lift-off layer and the first photoresist pattern.

2. The method for manufacturing a display device of claim 1, further comprising after forming the second electrode:
forming an optical layer on the second electrode through the photo-opening part.

3. The method for manufacturing a display device of claim 1, wherein the first lift-off layer overlaps with the pad area on a plane.

4. The method for manufacturing a display device of claim 1, wherein the first lift-off layer comprises polytetrafluoroethylene (PTFE).

5. The method for manufacturing a display device of claim 1, wherein the forming of the first lift-off layer comprises:
etching the preliminary first lift-off layer by a first solvent comprising fluorine by using the first photoresist pattern as a mask.

6. The method for manufacturing a display device of claim 5, wherein the first solvent comprises hydrofluoroether (HFE).

7. The method for manufacturing a display device of claim 1, wherein the removing the first lift-off layer and the first photoresist pattern comprises:
treating the first lift-off layer and the first photoresist pattern with a second solvent comprising fluorine.

8. The method for manufacturing a display device of claim 1, wherein preparing the substrate comprises:
preparing a base substrate in which the display area and the pad area are defined;
forming the first electrode on the base substrate to overlap with the display area;
forming a pixel definition layer defining a pixel opening part exposing a portion of the first electrode and comprising a liquid repelling part comprising a liquid repelling material; and
forming the intermediate layer on the first electrode.

9. The method for manufacturing a display device of claim 8, wherein at least a portion of the liquid repelling part is removed by the etching process during the forming of the first lift-off layer.

10. The method for manufacturing a display device of claim 8, wherein the forming the intermediate layer comprises:
forming a hole transport region on the first electrode;
forming an emission layer on the hole transport region; and
forming an electron transport region on the emission layer.

11. The method for manufacturing a display device of claim 8, wherein the forming the intermediate layer is performed through an inkjet process.

12. The method for manufacturing a display device of claim 1, wherein the forming the second electrode is performed through a deposition process.

13. The method for manufacturing a display device of claim 1, further comprising:
forming a preliminary second lift-off layer on the substrate;
forming a second photoresist pattern overlapping with the pad area, on the preliminary second lift-off layer;
etching the preliminary second lift-off layer to form a second lift-off layer exposing the display area;
forming an encapsulation layer on the second electrode using the second photoresist pattern as a mask; and
removing the second lift-off layer and the second photoresist pattern.

14. The method for manufacturing a display device of claim 13, wherein the second lift-off layer does not overlap the display area on a plane, and does not overlap the peripheral area on a plane.

15. The method for manufacturing a display device of claim 13, wherein the forming the second lift-off layer comprises:
etching the preliminary second lift-off layer by a third solvent comprising fluorine by using the second photoresist pattern as a mask.

16. The method for manufacturing a display device of claim 13, wherein the removing the second lift-off layer and the second photoresist layer comprises:
treating the second lift-off layer and the second photoresist pattern with a fourth solvent comprising fluorine.

17. A method for manufacturing a display device, the method comprising:
preparing a base substrate comprising a display area, the display area comprising multiple pixel areas and a pad area;
forming a first electrode and a pixel definition layer, on the base substrate, the pixel definition layer defining pixel-opening parts, each one of the pixel-opening parts overlapping a pixel area;
providing an intermediate layer in the pixel-opening parts by an inkjet printing method;
forming a first lift-off layer exposing the display area and comprising fluorine, and a first photoresist pattern in which a photo-opening part exposing the display area is defined;
forming a second electrode on the intermediate layer through the photo-opening part; and
removing the first lift-off layer and the first photoresist pattern.

18. The method for manufacturing a display device of claim 17, further comprising:
forming an optical layer on the second electrode through the photo opening part.

19. The method for manufacturing a display device of claim 17, wherein the forming of the first lift-off layer and the first photoresist pattern comprises:
forming a preliminary lift-off layer on the display area and the pad area;
forming the first photoresist pattern on the preliminary first lift-off layer; and
etching the preliminary first lift-off layer using the first photoresist pattern as a mask to form the first lift-off layer.

20. The method for manufacturing a display device of claim 19, wherein the pixel definition layer comprises:
a first pixel definition part on the base substrate; and
a second pixel definition part on the first pixel definition part and comprising a liquid-repelling material,
wherein at least a portion of the second pixel definition part is removed during the etching of the preliminary first lift-off layer.
